(19) United States
(12) Patent Application Publication
(10) Pub. No.: US 2025/0063957 A1
(43) Pub. Date: Feb. 20, 2025

(54) VERTICAL MEMORY DEVICE AND METHOD OF MANUFACTURING THE SAME

(71) Applicant: SAMSUNG ELECTRONICS CO., LTD., Suwon-si (KR)

(72) Inventors: Bonjae KOO, Suwon-si (KR); Seulji SONG, Suwon-si (KR); Youngsun SONG, Suwon-si (KR)

(73) Assignee: SAMSUNG ELECTRONICS CO., LTD., Suwon-si (KR)

(21) Appl. No.: 18/657,229

(22) Filed: May 7, 2024

(30) Foreign Application Priority Data
Aug. 18, 2023 (KR) 10-2023-0108547

(51) Int. Cl. H10N 70/00; H10B 63/00; H10B 63/10

(52) U.S. Cl. CPC H10N 70/826; H10B 63/10; H10B 63/84; H10N 70/841; H10N 70/8845

(57) ABSTRACT

According to an aspect of the disclosure, a vertical memory device may include: a substrate; a plurality of electrode structures extending in a vertical direction on the substrate; a word line cut disposed apart from the plurality of electrode structures in a horizontal direction and extending in the vertical direction; and a gate stack structure may include gate electrodes and interlayer insulating layers alternately stacked on the substrate along a sidewall of each of the plurality of electrode structures and the word line cut, wherein the gate electrodes may be electrically connected to the plurality of electrode structures. In a plan view, the word line cut may be wavy-shaped.

### CROSS-REFERENCE TO RELATED APPLICATION

This application is based on and claims priority under 35 U.S.C. § 119 to Korean Patent Application No. 10-2023-0108547, filed on Aug. 18, 2023, in the Korean Intellectual Property Office, the disclosure of which is incorporated by reference herein in its entirety.

### BACKGROUND

### 1. Field

The disclosure relates to a semiconductor memory device, and more particularly, to a vertical memory device and a method of manufacturing the same.

### 2. Description of Related Art

A vertical memory device having a three-dimensional cross-point stack structure has been suggested. In such a device, a memory cell is arranged at a point where two electrodes cross each other. Due to ongoing demand for increasingly high speed and high capacity memory devices, there is a desire to develop a new structure enabling reliable vertical memory devices having cross-point stack structures, that can be easily manufactured.

### SUMMARY

Embodiments of the disclosure provide a vertical memory device having a high aspect ratio and improved operation rate and leaning margin, and a method of manufacturing the vertical memory device.

Embodiments of the disclosure also provide a vertical memory device, with improved structural reliability in terms of trim pattern and word line cut, and a method of manufacturing the vertical memory device.

Technical goals to be achieved by the disclosure are not limited thereto, and other technical goals may be clearly understood to those skilled in the art based on the following description.

Additional aspects will be set forth in part in the description which follows and, in part, will be apparent from the description, or may be learned by practice of the presented embodiments.

According to an aspect of the disclosure, a vertical memory device may include: a substrate; a plurality of electrode structures extending in a vertical direction on the substrate; a word line cut disposed apart from the plurality of electrode structures in a horizontal direction and extending in the vertical direction; and a gate stack structure may include gate electrodes and interlayer insulating layers alternately stacked on the substrate along a sidewall of each of the plurality of electrode structures and the word line cut, wherein the gate electrodes may be electrically connected to the plurality of electrode structures. In a plan view, the word line cut may be wavy-shaped.

The plurality of electrode structures may constitute a plurality of lines in a first horizontal direction, and the word line cut may extend in a second horizontal direction perpendicular to the first horizontal direction.

The plurality of electrode structures may be disposed apart from each other in a first horizontal direction, further may include: a plurality of partition pillars each disposed between the plurality of electrode structures, and passing through at least a portion of the gate stack structure in the vertical direction.

In the plan view, each of the plurality of electrode structures may have a circular cross-section, and each of the plurality of partition pillars may include concave portions in the first horizontal direction.

In the plan view, the plurality of electrode structures and the plurality of partition pillars may be wavy-shaped.

In the plan view, the plurality of electrode structures may be disposed in a hexagonal array.

According to an aspect of the disclosure, a vertical memory device may include: a substrate; a plurality of electrode structures extending in a vertical direction on the substrate and constituting a plurality of lines in a first horizontal direction; a plurality of partition pillars extending on the substrate in the vertical direction and contacting at least one of the plurality of electrode structures; a word line cut disposed apart from the plurality of electrode structures in a horizontal direction and extending in the vertical direction; and a gate stack structure may include gate electrodes and interlayer insulating layers alternately stacked on the substrate along a sidewall of each of the plurality of electrode structures and the word line cut, wherein the gate electrodes may be electrically connected to the plurality of electrode structures. In a plan view, the word line cut may be wavy-shaped, and each of the plurality of electrode structures may include: a vertical electrode extending in the vertical direction on the substrate; and a switching material layer surrounding the vertical electrode and extending in the vertical direction.

The switching material layer may have a circular pipe shape surrounding the vertical electrode and extending in the vertical direction.

The switching material layer may include a plurality of switching elements disposed apart from one another by layer in the vertical direction, and each of the plurality of switching elements may have a shape of two arcs facing each other and surrounding the vertical electrode.

The vertical memory device further may include: a first carbon layer disposed between the vertical electrode and the switching material layer; and a second carbon layer disposed between the gate electrodes and the switching material layer.

The first carbon layer and the second carbon layer have a circular pipe shape.

The first carbon layer may have a circular pipe shape, and the second carbon layer may include second carbon elements corresponding to switching elements, and each of the second carbon elements may have a shape of two arcs.

A bottom surface of the vertical electrode, bottom surfaces of the plurality of partition pillars, and a bottom surface of the gate stack structure may be at a same vertical level.

According to an aspect of the disclosure, a vertical memory device may include: a substrate; a plurality of electrode structures extending in a vertical direction on the substrate and constituting a plurality of lines in a first horizontal direction; a plurality of partition pillars each extending on the substrate in the vertical direction and contacting at least one of the plurality of electrode structures; a plurality of trim patterns contacting the plurality of electrode structures or the plurality of partition pillars and extending in the vertical direction on the substrate; a word line cut disposed apart from each of the plurality of electrode structures, the plurality of partition pillars, and the plurality of trim patterns in a horizontal direction and extending in the vertical direction; and a gate stack structure may include gate electrodes and interlayer insulating layers alternately stacked on the substrate along a sidewall of each of the plurality of electrode structures, the plurality of partition pillars, and the word line cut, wherein the gate electrodes may be electrically connected to the plurality of electrode structures. In a plan view, each of the plurality of trim patterns and the word line cut may be wavy shaped, the plurality of electrode structures and the plurality of partition pillars may form a plurality of sub channels extending in the first horizontal direction, the plurality of trim patterns may form a connection channel connecting the plurality of sub channels that may be apart from each other in a second horizontal direction, and each of the plurality of electrode structures may include: a vertical electrode extending in the vertical direction on the substrate; and a switching material layer surrounding the vertical electrode and extending in the vertical direction.

The vertical memory device further may include: a first carbon layer disposed between the vertical electrode and the switching material layer; and a second carbon layer disposed between each of the gate electrodes and the switching material layer.

Each of the gate electrodes may include a first plate electrode and a second plate electrode disposed apart from each other in the horizontal direction and disposed at a same vertical level, the first plate electrode and the second plate electrode each may have a comb shape including a plurality of protrusion electrode portions, and each of the plurality of electrode structures may contact a protrusion portion of the first plate electrode and a protrusion portion of the second plate electrode.

A first thickness of each of the interlayer insulating layers in the vertical direction may be greater than a second thickness of each of the gate electrodes in the vertical direction.

In the plan view, the plurality of electrode structures, the plurality of partition pillars, and the plurality of trim patterns may have a serpentine line shape.

A first trim pattern and a second trim pattern may be disposed apart from each other in the first horizontal direction at staggered positions in the second horizontal direction.

In the plan view, the plurality of electrode structures, the plurality of partition pillars, and the plurality of trim patterns may be wavy-shaped.

### BRIEF DESCRIPTION OF DRAWINGS

The above and other aspects, features, and advantages of certain embodiments of the present disclosure will be more apparent from the following description taken in conjunction with the accompanying drawings, in which:

FIG. 1A is a plan view of a vertical memory device according to an embodiment;

FIG. 1B is a cross-sectional view of a vertical memory device according to an embodiment.

FIG. 1C is a perspective view of a vertical memory device according to an embodiment;

FIG. 2A is a plan view of a vertical memory device according to an embodiment;

FIG. 2B is a cross-sectional view of a vertical memory device according to an embodiment.

FIG. 2C is a perspective view of a vertical memory device according to an embodiment;

FIG. 3A is a plan view of a vertical memory device according to an embodiment;

FIG. 3B is a cross-sectional view of a vertical memory device according to an embodiment.

FIG. 3C is a perspective view of a vertical memory device according to an embodiment;

FIG. 4 is a cross-sectional view showing an embodiment of a process of manufacturing an embodiment of the vertical memory device;

FIG. 5A is a plan view showing an embodiment of a process of manufacturing an embodiment of the vertical memory device;

FIG. 5B is a cross-sectional view showing an embodiment of a process of manufacturing an embodiment of the vertical memory device;

FIG. 6A is a plan view showing an embodiment of a process of manufacturing an embodiment of the vertical memory device;

FIG. 6B is a cross-sectional view showing an embodiment of a process of manufacturing an embodiment of the vertical memory device;

FIG. 7A is a plan view showing an embodiment of a process of manufacturing an embodiment of the vertical memory device;

FIG. 7B is a cross-sectional showing an embodiment of a process of manufacturing an embodiment of the vertical memory device;

FIG. 8A is a plan view showing an embodiment of a process of manufacturing an embodiment of the vertical memory device;

FIG. 8B is a cross-sectional showing an embodiment of a process of manufacturing an embodiment of the vertical memory device;

FIG. 9A is a plan view showing an embodiment of a process of manufacturing an embodiment of the vertical memory device;

FIG. 9B is a cross-sectional showing an embodiment of a process of manufacturing an embodiment of the vertical memory device;

FIG. 10A is a plan view showing an embodiment of a process of manufacturing an embodiment of the vertical memory device;

FIG. 10B is a cross-sectional showing an embodiment of a process of manufacturing an embodiment of the vertical memory device;

FIG. 11 is a plan view showing an embodiment of a process of manufacturing an embodiment of the vertical memory device;

FIG. 12A is a plan view showing an embodiment of a process of manufacturing an embodiment of the vertical memory device;

FIG. 12B is a cross-sectional showing an embodiment of a process of manufacturing an embodiment of the vertical memory device;

FIG. 13A is a plan view showing an embodiment of a process of manufacturing an embodiment of the vertical memory device;

FIG. 13B is a cross-sectional view showing an embodiment of a process of manufacturing an embodiment of the vertical memory device;

FIG. 14A is a plan view showing an embodiment of a process of manufacturing an embodiment of the vertical memory device;

FIG. 14B is a cross-sectional view showing an embodiment of a process of manufacturing an embodiment of the vertical memory device;

FIG. 15 is a cross-sectional view showing an embodiment of a process of manufacturing an embodiment of the vertical memory device;

FIG. 16 is a cross-sectional view showing an embodiment of a process of manufacturing an embodiment of the vertical memory device;

FIG. 17A is a plan view showing an embodiment of a process of manufacturing an embodiment of the vertical memory device; and

FIG. 17B is a cross-sectional view showing an embodiment of a process of manufacturing an embodiment of the vertical memory device.

### DETAILED DESCRIPTION

Hereinafter, embodiments of the disclosure will be described in detail with reference to the accompanying drawings. Same reference numerals will be given to same components in the drawings, and descriptions thereof will not be repeatedly given.

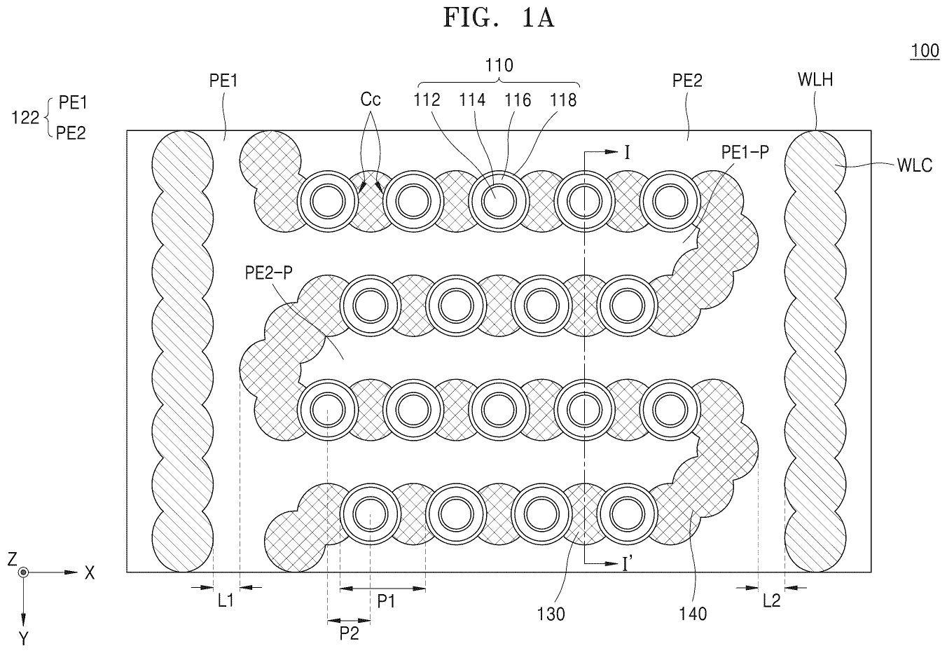

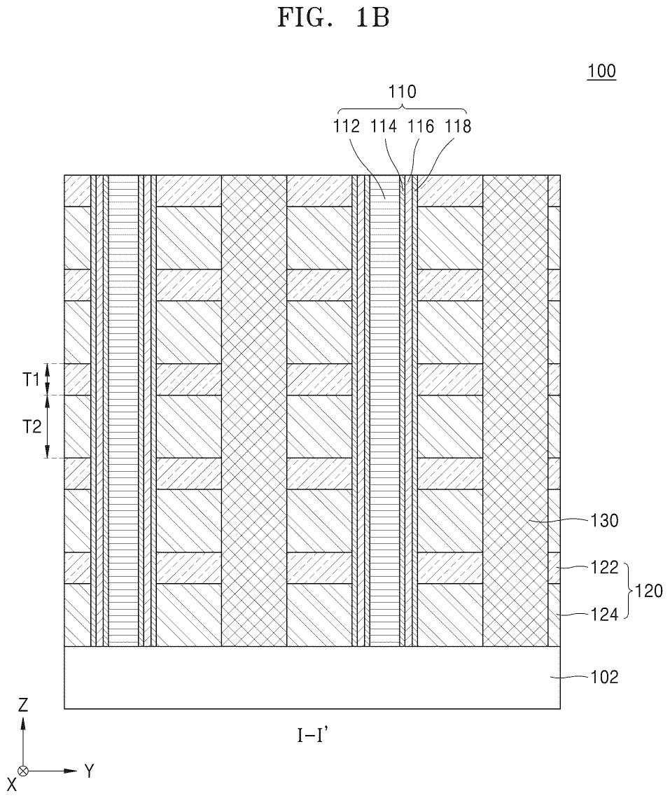

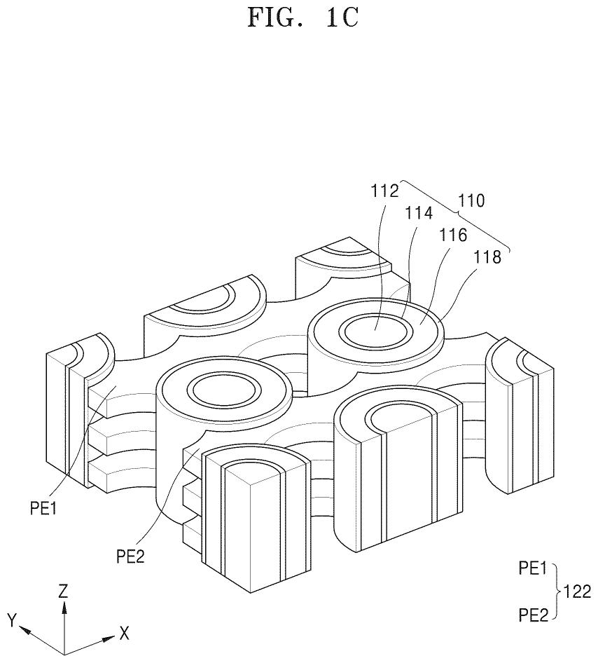

FIGS. 1A to 1C are a plan view, a cross-sectional view, and a perspective view of a vertical memory device 100 according to an embodiment.

Referring to FIGS. 1A to 1C, the vertical memory device 100 of the embodiment may include a substrate 102, an electrode structure 110, a gate stack structure 120, a partition pillar 130, a trim pattern 140, and a word line cut (WLC).

The substrate 102 may include silicon (Si), e.g., monocrystalline Si, polycrystalline Si (poly Si), or amorphous Si. However, a material of the substrate 102 is not limited to Si. For example, in some embodiments, the substrate 102 may include a Group IV semiconductor such as germanium (Ge), a Group IV-IV compound semiconductor such as silicon germanium (SiGe) or silicon carbide (SiC), or a Group III-V compound semiconductor such as gallium arsenide (GaAs), indium arsenide (InAs), or indium phosphide (InP).

The substrate 102 may include an Si bulk substrate. In addition, the substrate 102 may include a Silicon-on-Insulator (SOI) substrate or a Germanium-on-Insulator (GeOI) substrate. The substrate 102 is not limited to a bulk substrate, an SOI substrate, and/or a GeOI substrate, and may also include a substrate based on an epitaxial wafer, a polished wafer, and/or an annealed wafer. The substrate 102 may include a conductive region, e.g., a well doped with impurities or various structures doped with impurities. In addition, the substrate 102 may constitute a p-type substrate or an n-type substrate according to types of impurity ions used for doping. A peripheral circuit and a wiring layer connected thereto may be arranged in a region of the substrate 102.

In the disclosure, a direction parallel to a main surface of the substrate 102 can be defined as a horizontal direction (an X direction and/or a Y direction), and a direction perpendicular to the horizontal direction (the X direction and/or the Y direction) can be defined as a vertical direction (a Z direction). In the disclosure, between two surfaces apart from each other in the vertical direction (the Z direction), a surface near the substrate 102 can be defined as a bottom surface, and a surface opposite the bottom surface can be defined as a top surface.

The electrode structure 110 may be arranged in a two-dimensional array structure on a horizontal plane, as shown in FIG. 1A. More particularly, a plurality of the electrode structures 110 may be arranged apart from one another in the horizontal direction (the X direction and/or the Y direction). The plurality of electrode structures 110 may constitute a line in a first horizontal direction (the X direction), and the plurality of electrode structures 110 adjacent to each other in the first horizontal direction (the X direction) may be separated from each other by the partition pillar 130.

The plurality of electrode structures 110 constituting the line in the first horizontal direction (the X direction) may be arranged in a zigzag shape in the first horizontal direction (the X direction) on two lines adjacent to each other in the second horizontal direction (the y direction). For example, the plurality of electrode structures 110 may be arranged with a first pitch P1 in the first horizontal direction (the X direction), and the plurality of electrode structures 110 may be arranged with an offset of a second pitch P2 in the first horizontal direction (the X direction) between two lines adjacent to each other in the second horizontal direction (the Y direction). For example, the second pitch P2 may be half the first pitch P1. That is, in a plan view, the plurality of electrode structures 110 may be arranged in the form of a honeycomb array and/or a hexagonal array. In another embodiment, in a plan view, the plurality of electrode structures 110 may be arranged in a matrix shape. In other embodiments, the plurality of electrode structures 110 may be arranged in various shapes.

The electrode structure 110 may have a cylinder shape extending in a direction perpendicular to a top surface (or a main surface) of the substrate 102, i.e., the vertical direction (the Z direction). However, the shape of the electrode structure 110 is not limited to a cylinder shape. For example, in some embodiments, the electrode structure 110 may have an elliptical cylinder shape or a polygon pillar shape.

The electrode structure 110 may include a vertical electrode 112, a first carbon layer 114, a switching material layer 116, and a second carbon layer 118. In some embodiments, at least one of the first carbon layer 114 and the second carbon layer 118 may be omitted. In the vertical memory device 100 of the present embodiment, the vertical electrode 112 may constitute a vertical bit line.

The vertical electrode 112 may have a cylinder shape extending in the vertical direction (the Z direction) from the top surface (or the main surface) of the substrate 102. However, the shape of the vertical electrode 112 is not limited to the cylinder shape. For example, the vertical electrode 112 may have an elliptical cylinder shape or a polygonal pillar shape. The vertical electrode 112 may include a conductive material. For example, the vertical electrode 112 may include a doped semiconductor material, a metal, a conductive metal oxide, a conductive metal nitride, and the like. A conductive contact may be arranged under and/or on the electrode structure 110, and the conductive contact may be electrically connected to the vertical electrode 112.

The first carbon layer 114 may cover a side surface of the vertical electrode 112. Accordingly, the first carbon layer 114 may have a circular pipe shape in which a top surface and a bottom surface thereof are open. In other embodiments, the first carbon layer 114 may cover the side surface and a bottom surface of the vertical electrode 112. Accordingly, the first carbon layer 114 may have a circular pipe shape in which a surface (e.g., the bottom surface) thereof is closed.

The switching material layer 116 may cover a side surface of the first carbon layer 114. Accordingly, the switching material layer 116 may have a circular pipe shape in which a top surface and a bottom surface thereof are open. In another embodiment, the switching material layer 116 may cover the side surface and the top surface of the first carbon layer 114. Accordingly, the switching material layer 116 may have a circular pipe shape in which a surface thereof (e.g., the bottom surface) is closed.

The switching material layer 116 may function as an autonomous selector storage device. The autonomous selector storage device may indicate a device configured to function as both of a selector and a storage device. Due to characteristics such as the switching material layer 116, the vertical memory device 100 according to the disclosure may be referred to a selector-only memory (SOM) device.

The switching material layer 116 may include a chalcogenide alloy and/or a chalcogenide material such as glass, which functions as the autonomous selector storage device. The switching material layer 116 may be configured to respond to an applied voltage such as a program pulse. For example, in response to an applied voltage less than a threshold voltage, the switching material layer 116 may be maintained in an electrically non-conductive state, e.g., an “off” state. In addition, in response to an applied voltage greater than the threshold voltage, the switching material layer 116 may be changed into an electrically conductive state, e.g., an “on” state. The threshold voltage of the switching material layer 116 may change based on the polarity of the applied voltage. For example, the threshold voltage of the switching material layer 116 may change based on the polarity of the program pulse. Accordingly, in the vertical memory device 100 according to the present embodiment, a bipolar voltage may be used for operation.

The switching material layer 116 may include a chalcogenide material that does not have a phase change during operation. The switching material layer 116 may include, for example, indium (In)-stibium (Sb)-tellurium (Te) (IST), germanium (Ge), Sb—Te (GST), Te-arsenide (As)—Ge (Ovonic Threshold Switch: OTS), Ge, Sb, Te, silicon (Si), nickel (Ni), gallium (Ga), As, silver (Ag), tin (Sn), gold (Au), lead (Pb), bismuth (Bi), In, Se, oxygen (O), sulfur(S), nitrogen (N), carbon (C), yttrium (Y), scandium (Sc), and combinations thereof. Here, IST may include, for example, In₂Sb₂Te₅, InSb₂Te₄, InSb₄Te₇, and the like. GST may include, for example, Ge₈Sb₅Te₈, Ge₂Sb₂Te₅, GeSb₂Te₄, GeSb₄Te₇, Ge₄Sb₄Te₇, and the like. In some embodiments, the chalcogenide material may include glass or amorphous chalcogenide.

The second carbon layer 118 may cover a side surface of the switching material layer 116. Accordingly, the second carbon layer 118 may have a circular pipe shape in which a top surface and a bottom surface thereof are open. In another embodiment, the second carbon layer 118 may cover the side surface of the switching material layer 116 and a bottom surface of the switching material layer 116. Accordingly, the second carbon layer 118 may have a circular pipe shape in which a surface (e.g., the bottom surface) thereof is closed.

When a conductive contact is arranged under the electrode structure 110, the conductive contact may directly contact the vertical electrode 112 and may be electrically connected thereto. In another embodiment, when each of the first carbon layer 114, the switching material layer 116, and/or the second carbon layer 118 has a circular pipe structure in which the bottom surface thereof is closed, the conductive contact may pass through the first carbon layer 114, the switching material layer 116, and/or the second carbon layer 118 and may be electrically connected to the vertical electrode 112.

The gate stack structure 120 may include gate electrodes 122 and interlayer insulating layers 124. As shown in FIG. 1B, the gate electrodes 122 and the interlayer insulating layers 124 may be alternately stacked on the substrate 102 along a sidewall of the electrode structure 110. In the vertical memory device 100 according to the present embodiment, the gate electrode 122 may constitute a word line.

The gate electrode 122 may have a plate shape. In other words, on each layer, the gate electrodes 122 may have a structure configured to be integrally connected to each other in a plate shape. Accordingly, the gate electrode 122 may also be referred to as a plate electrode. In addition, in some embodiments, the gate electrode 122 may also be referred to as a word line plate.

In the vertical memory device 100 of the present embodiment, the gate electrode 122 may be in the form of a split plate electrode. For example, in each layer, the gate electrode 122 may include a first plate PE1 on left and a second plate electrode PE2 on right with reference to the first horizontal direction (the X direction). In addition, the first plate electrode PE1 and the second plate electrode PE2 may have staggered comb shapes. In addition, with reference to a line in which the electrode structures 110 are arranged in the first horizontal direction (the X direction), the first plate electrode PE1 and the second plate electrode PE2 may be arranged at two sides of the line in the second horizontal direction (the Y direction). In addition, the first plate electrode PE1 and the second plate electrode PE2 may each have a protrusion portion, and a protrusion portion PE1-P of the first plate electrode PE1 and a protrusion portion PE2-P of the second plate electrode PE2 may each contact the plurality of electrode structures 110.

In the vertical memory device 100 of the present embodiment, as the gate electrode 122 has the form of a split plate electrode, an operation rate of the vertical memory device 100 may be improved by minimizing parasitic capacitance of a word line. In addition, as the gate electrode 122 is in the form of a split plate electrode, an area in which a cell contacts the gate electrode 122 may be minimized and cell leakage may be reduced, and thus, a programming current may increase.

The gate electrode 122 may include a conductive material, e.g., a doped semiconductor material, a metal, a conductive metal nitride, a conductive metal oxide, and the like. The interlayer insulating layer 124 may include an insulating material, e.g., silicon oxide, silicon nitride, silicon oxynitride, and the like. In the vertical memory device 100 according to the present embodiment, the interlayer insulating layer 124 may include silicon oxide. However, a material of the interlayer insulating layer 124 is not limited to silicon oxide.

The gate electrode 122 may have a first thickness T1 in the vertical direction (the Z direction), and the interlayer insulating layer 124 may have a second thickness T2 in the vertical direction (the Z direction). The fist thickness T1 may be less than the second thickness T2. In another embodiment, the first thickness T1 may be equal to the second thickness T2 or greater.

The partition pillar 130 may be arranged between the plurality of electrode structures 110 in the first horizontal direction (the X direction). A shape of the partition pillar 130 is approximately a cylinder, but an outer portion of the partition pillar 130 may be partially impinged by the electrode structures 110 arranged at two sides of the partition pillar 130 in the first horizontal direction (the X direction). Accordingly, the partition pillar 130 may include concave portions (Cc) at two sides thereof in the first horizontal direction (the X direction). In addition, in a plan view, the plurality of electrode structures 110 and the partition pillar 130 may extend in a wavy shape in the first horizontal direction (the X direction). That is, in a plan view, the plurality of electrode structures 110 and the partition pillar 130 may extend in the first horizontal direction (the X direction) and form a line having a wavy shape.

The partition pillar 130 may include an insulating material, for example, silicon oxide, silicon nitride, or silicon oxynitride. However, a material of the partition pillar 130 is not limited to the aforementioned materials. For reference, the interlayer insulating layer 124 and the partition pillar 130 are omitted in FIG. 1C, but the partition pillar 130 may be formed in the first horizontal direction (the X direction) in an empty space between the electrode structures 110, and the interlayer insulating layer 124 may be formed in the vertical direction (the Z direction) in an empty space between the gate electrodes 122. Accordingly, the partition pillar 130 may only contact the second carbon layer 118 among components of the electrode structure 110.

The trim pattern 140 may be arranged at two edge portions of a cell block in the first horizontal direction (the X direction). Here, the cell block can be defined by the word line cut (WLC) extending in the second horizontal direction (the Y direction). The trim pattern 140 may have a wavy shape on a plan view. In addition, the trim pattern 140 may have a width to cover at least one partition pillar 130 in the second horizontal direction (the Y direction). That is, among lines in which the electrode structures 110 are arranged in the first horizontal direction (the X direction), two lines adjacent to each other in the second horizontal direction (the Y direction) may contact each other through the electrode structure 110 contacting the trim pattern 140 arranged on left or right in the first direction (the X direction).

In addition, the trim patterns 140 on left in the first horizontal direction (the X direction) and the trim patterns 140 on right in the first horizontal direction (the X direction) may be arranged at staggered positions in the second horizontal direction (the Y direction). In addition, two trim patterns 140 facing each other in the first horizontal direction (the X direction) and adjacent to each other in the second horizontal direction (the Y direction) may together cover a line in which the electrode structures 110 are arranged in the first horizontal direction (the X direction), and may be arranged in a point-symmetry structure with reference to a portion of the line, e.g., the electrode structure 110 of a center portion of the line.

The trim pattern 140 may include an insulating material, for example, silicon oxide, silicon nitride, or silicon oxynitride. In the vertical memory device 100 according to the present embodiment, the trim pattern 140 may be formed together with the partition pillar 130. Accordingly, the trim pattern 140 may include a material identical to the material of the partition pillar 130. In the disclosure, the partition pillar 130 and the trim pattern 140 are merely used as formal divisions for convenience of explanation, and may include components formed in a same process. In another embodiment, the trim pattern 140 may include a material different from the material of the partition pillar 130.

With reference to the first horizontal direction (the X direction), a horizontal distance from a trim pattern arranged leftmost to a word line cut (WLC) adjacent thereto may be referred to a first distance L1, and a horizontal distance from a trim patter arranged rightmost to a word line cut (WLC) adjacent thereto may be referred to a second distance L2. The first distance L1 and the second distance L2 may be identical to each other. Accordingly, the uniformity of process increases, and deviation of the performance of the vertical memory device 100 may be reduced.

In a plan view, the electrode structure 110, the partition pillar 130, and the trim pattern 140 may together form a line extending in a serpentine shape. For example, the electrode structure 110 and the plurality of partition pillars 130 may form a plurality of sublines extending in the first horizontal direction (the X direction). In addition, the trim patterns 140 may include a connection line to connect the plurality of sublines apart from each other in the second horizontal direction (the Y direction).

The word line cut (WLC) may extend in the second horizontal direction (the Y direction) on a plane and may have a wavy shape (i.e. be wavy-shaped). The word line cut (WLC) may be arranged in the word line cut hole (WLH). In a plan view, a direction in which the word line cut (WLC) extends may be different from a direction in which the electrode structure 110 and the partition pillar 130 extend. For example, in a plan view, the direction in which the word line cut (WLC) may be perpendicular to the direction in which the electrode structure 110 and the partition pillar 130 extends.

As described above, the word line cut (WLC) may separate a plurality of cell blocks adjacent to each other in the first horizontal direction (the X direction). The cell block may extend in the second horizontal direction (the Y direction), and a step-shaped pad may be arranged at an edge portion of the cell block in the second horizontal direction (the Y direction), and a vertical contact may be connected to the pad. A word line voltage may be applied to the gate electrode 122 of each layer through the vertical contact and the pad.

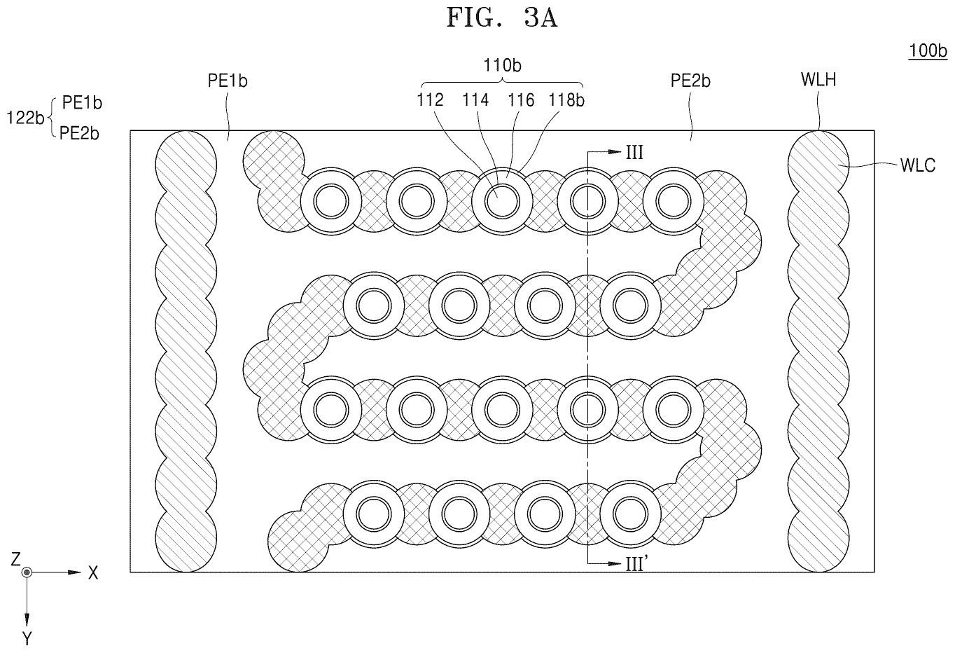

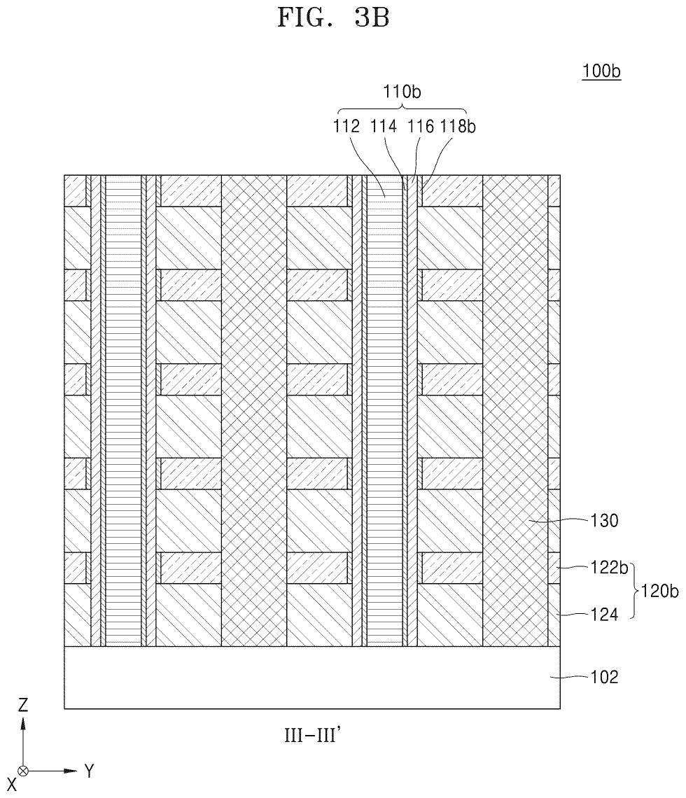

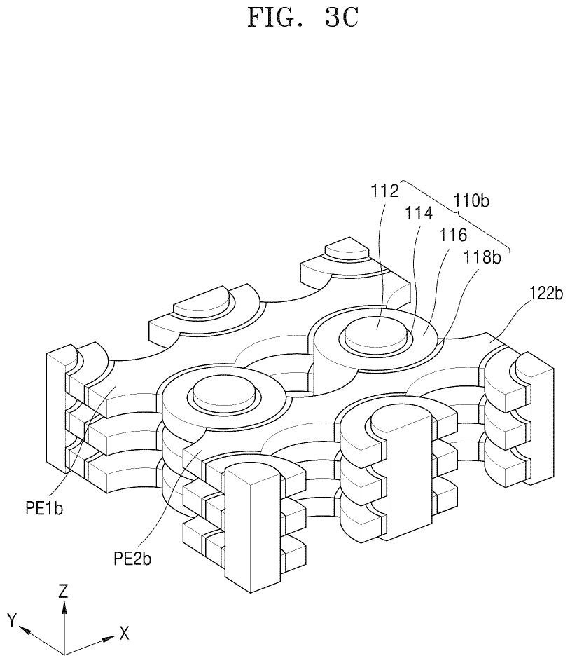

The vertical memory device 100 of the present embodiment may have a vertical structure in which the electrode structure 110 including the vertical electrode 112 and the switching material layer 116 may extend in the vertical direction and the gate electrodes 122 are stacked along the sidewall of the electrode structure 110. Accordingly, the reliability of the vertical memory device 100 of the present embodiment may be significantly improved, and a high-capacity memory device may be implemented. Furthermore, in the vertical memory device 100 of the present embodiment, the electrode structures 110 may be arranged in the form of a line in the first horizontal direction (the X direction) and may be separated from one another by the partition pillar 130 having a cylinder shape. As described above, due to a structure in which the partition pillar 130 having a cylinder shape is arranged between the electrode structures 110, leaning defects that may occur while forming a line pattern having a high aspect ratio in the gate stack structure 120 including tens to hundreds of layers may be effectively prevented. In addition, as the open holes to form the word line cut (WLC) and the trim patterns 140 are simultaneously formed in a same process, the word line cut (WLC) and the trim pattern 140 may have a same tilting direction. Accordingly, breakage and/or bursting defects of each of the word line cut (WLC) and the trim pattern 140 may be prevented. Accordingly, the structural reliability of the vertical memory device 100 may be improved. As the word line cut (WLC) and the trim patterns 140 are simultaneously formed in a same process, in a plan view, the word line cut (WLC) may have a wavy shape that is similar to the wavy shape of the trim pattern 140. The leaning defects will be described in further detail with reference to FIGS. 3A to 3C.

In addition, as the open holes to form the word line cut (WLC) and the trim pattern 140 are simultaneously formed in a same process, distances from the plurality of trim patterns 140 to the word line cuts (WLC) adjacent thereto may be substantially identical. Accordingly, deviations in the electrical characteristics of the vertical memory device 100 may be reduced.

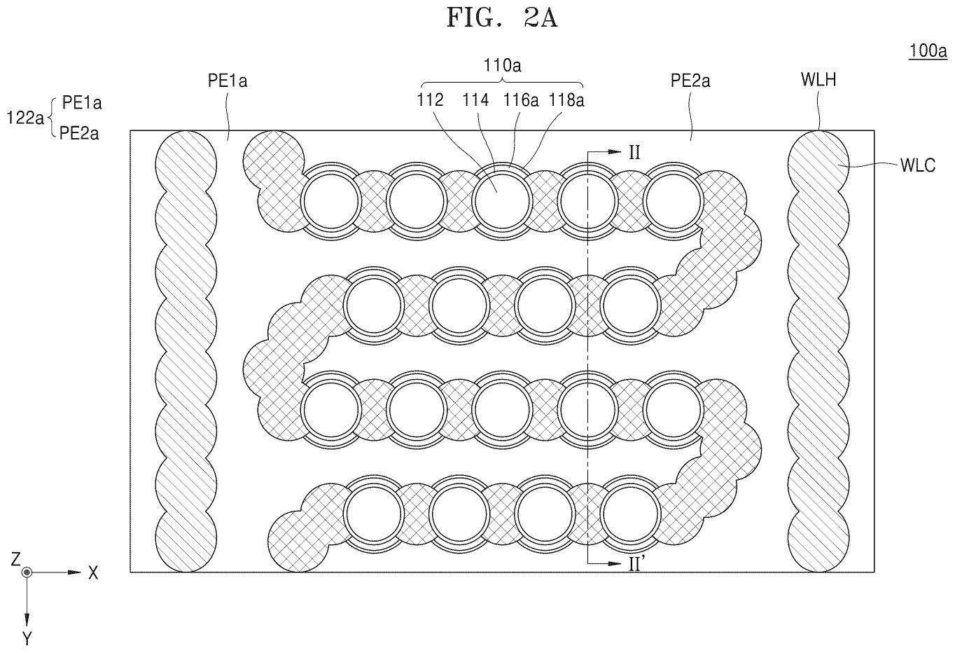

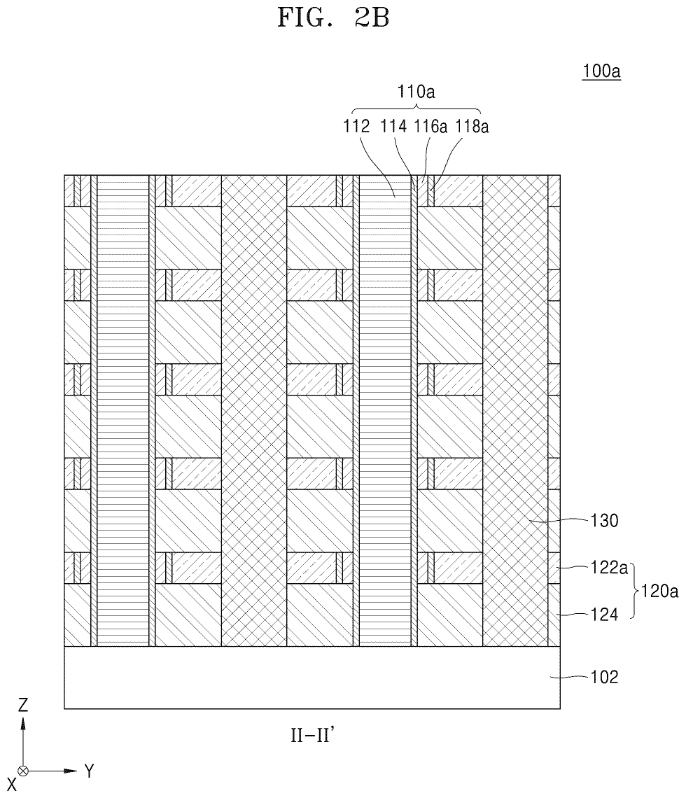

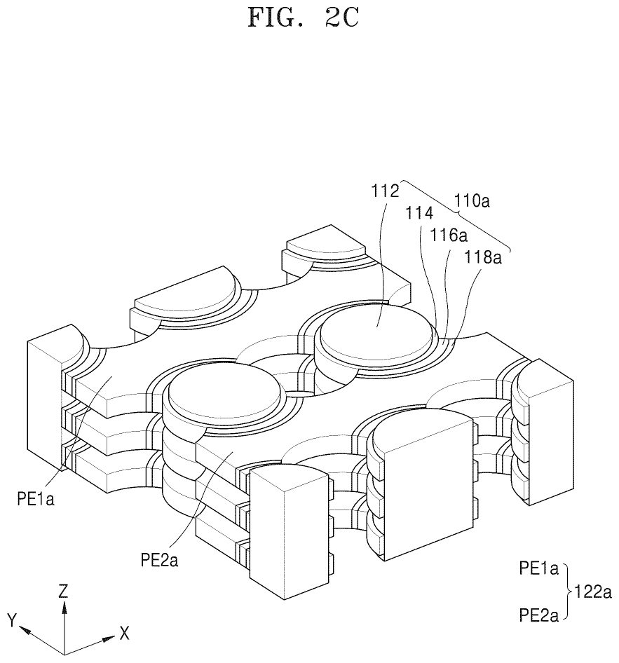

FIGS. 2A to 2C are a plan view, a cross-sectional view, and a perspective view of a vertical memory device 100a according to an embodiment, respectively. Descriptions with reference to FIGS. 1A to 1C will be briefly given or omitted.

Referring to FIGS. 2A to 2C, the vertical memory device 100a according to the present embodiment may include the substrate 102, an electrode structure 110a, a gate stack structure 120a, the partition pillar 130, the trim pattern 140, and the word line cut (WLC). Same descriptions as the substrate 102, the partition pillar 130, the trim pattern 140, and the word line cut (WLC) of the vertical memory device 100 shown in FIG. 1A will be applied to the substrate 102, the partition pillar 130, the trim pattern 140, and the word line cut (WLC) of the vertical memory device 100a. In the gate stack structure 120a, a width in the second horizontal direction (the Y direction) of a gate electrode 122a may decrease at a portion contacting the electrode structure. The width of the gate electrode 122a will be described in further detail in the following descriptions regarding the electrode structure 110a.

The electrode structures 110a may be arranged in a two-dimensional array structure on a horizontal plane. More particularly, the electrode structures 110a may constitute a line in the first horizontal direction (the X direction), and a plurality of the electrode structures 110 adjacent to each other in the first horizontal direction (the X direction) may be separated from each other by the partition pillar 130. In addition, the plurality of electrode structures 110a on two lines adjacent to each other in the second horizontal direction (the Y direction) may be electrically connected to the gate electrode 122a of the gate stack structure 120a. In addition, the plurality of electrode structures 110a constituting the line in the first horizontal direction (the X direction) may be arranged in a zigzag shape in the first horizontal direction (the X direction) on two lines adjacent to each other in the second horizontal direction (the Y direction). That is, in a plan view, the plurality of electrode structures 110a may be arranged in the form of a honeycomb array and/or a hexagonal array. In another embodiment, in a plan view, the plurality of electrode structures 110a may be arranged in the form of a matrix. In other embodiments, the plurality of electrode structures 110a may be arranged in various shapes.

The electrode structure 110a may include the vertical electrode 112, the first carbon layer 114, a switching material layer 116a, and a second carbon layer 118a. In some embodiments, at least one of the first carbon layer 114 and the second carbon layer 118a may be omitted. In the vertical memory device 100a of the present embodiment, the vertical electrode 112 may constitute a vertical bit line.

The vertical electrode 112 may have a cylinder shape extending in the vertical direction (the Z direction) from the top surface of the substrate 102. However, the shape of the vertical electrode 112 is not limited to a cylinder shape. For example, the vertical electrode 112 may have an elliptical cylinder shape or a polygonal pillar shape. A conductive contact may be arranged under and/or on the electrode structure 110a, and the conductive contact may be connected to the vertical electrode 112.

The first carbon layer 114 may cover the side surface of the vertical electrode 112. Accordingly, the first carbon layer 114 may have a circular pipe shape in which a top surface and a bottom surface thereof are open. In other embodiments, the first carbon layer 114 may cover the side surface and the bottom surface of the vertical electrode 112. Accordingly, the first carbon layer 114 may have the circular pipe shape in which the surface (e.g., the bottom surface) thereof is closed.

The switching material layer 116a may include a plurality of switching elements apart from one another by layers in a direction perpendicular to the main surface of the substrate 102, i.e., the vertical direction (the Z direction). Each of the switching elements may have a shape of two arcs facing each other and surrounding a portion of the first carbon layer 114. For example, the switching elements of the switching material layer 116a may be arranged with an arc shape only on layers where the gate electrode 122a of the gate stack structure 120a is located. As shown in FIGS. 2A and 2C, switching material layer 116a may not form a complete circle around partition pillars 130 and carbon layer 114. More particularly, each of the switching elements of the switching material layer 116a may not surround the partition pillars 130 at two sides of the switching material layer 116a in the first horizontal direction (the X direction). Accordingly, the first carbon layer 114 may contact the partition pillar 130 in the first horizontal direction (the X direction). The switching material elements on the switching material layer 116a may also be apart and separated from switching elements on other layers in the vertical direction (the Z direction).

With this configuration, as the switching material layer 116a includes the switching elements and has a structure in which the switching elements are separated in the vertical direction (the Z direction), diffusion between cells in the vertical direction (the Z direction) may be inhibited, and the reliability of the memory device may be improved. Characteristics of operation of the switching material layer 116a, particular materials of the switching material layer 116a, and the like are as described above with reference to the switching material layer 116a of the vertical memory device 100 shown in FIGS. 1A to 1C.

The second carbon layer 118a may include a plurality of second carbon elements arranged apart by layers in the vertical direction (the Z direction) and correspond to the switching elements of the switching material layer 116a. Each of the second carbon elements may have a shape of two arcs surrounding a switching element on a corresponding switching material layer 116a. More particularly, as shown in FIGS. 2A to 2C, as the second carbon elements of the second carbon layer 118a and the switching elements of the switching material layer 116a have a shape of two arcs, the first carbon layer 114 may contact the partition pillars 130 at two sides of the electrode structure 110a in the first horizontal direction (the X direction). Like in the switching material layer 116a, in the second carbon layer 118a, the second carbon elements may be apart and separated from second carbon elements on other layers in the vertical direction (the Z direction). Accordingly, the partition pillar 130 may contact each of the first carbon layer 114, the switching material layer 116a, and the second carbon layer 118a among the components of the electrode structure 110a.

Due to characteristics of the manufacturing process, the vertical electrode 112 of this embodiment may have a greater horizontal radius than that of the vertical electrode 112 of the embodiment of FIGS. 1A to 1C, the dimensions of all other components of the electrode structures 110, 110a being equal. In other words, when a diameter of an open hole except to form the electrode structure 110a is identical to a diameter of an open hole to form the electrode structure 110 in the vertical memory device 100 shown in FIGS. 1A to 1C (assuming thicknesses of the first carbon layers 114, the switching material layer 116, and the second carbon layer 118 of the electrode structure 110 are respectively identical to thicknesses of the first carbon layer 114, the switching material layer 116a, and the second carbon layer 118a of the electrode structure 110a), a size of the vertical electrode 112 of the electrode structure 110a (e.g., a horizontal radius of the vertical electrode 112 of the electrode structure 110a) may be greater than a horizontal radius of the vertical electrode 112 of the electrode structure 110 shown in FIGS. 1A to 1C. For example, when the second carbon layers 118 and 118a are thinner, a horizontal radius of the vertical electrode 112 of the electrode structure 110a may be almost similar to a horizontal radius of an entire portion of the electrode structure 110a. In addition, as the switching material layer 116a and the second carbon layer 118a in the electrode structure 110a are arranged in the shape of two arcs at two sides in the second horizontal direction (the Y direction), a width in the second horizontal direction (the Y direction) of the gate electrode 122a of the gate stack structure 120a may decrease at a portion contacting the second carbon layer 118a.

According to embodiments, the vertical electrode 112 of the electrode structure 110 of the vertical memory device 100 shown in FIGS. 1A to 1C and the vertical electrode 112 of the electrode structure 110a of the vertical memory device 100 of the present embodiment may have a substantially same size. In that case, the open hole including the recesses for forming the electrode structure 110a may have a size of the vertical electrode 112 of the electrode structure 110a or a size including the first carbon layer 114. Hereinafter, through an enlargement process and the like, the switching material layer 116a may have a thickness identical to a thickness of the switching material layer 116, and the second carbon layer 118a have a thickness identical to a thickness of the second carbon layer 118. As a result, in terms of the diameter in the second horizontal direction (the Y direction), the electrode structure 110a and the electrode structure 110 may have a substantially same size.

Like the vertical memory device 100 shown in FIGS. 1A to 1C, the vertical memory device 100a of the present embodiment have effects of increase in the integration, improvement of an operation rate, increase in a programming current, prevention of the leaning defect, decrease in deviation of electrical characteristics, and reduction in breakage and/or bursting defects. In addition, as the vertical memory device 100a of the present embodiment has a structure in which the switching elements of the switching material layer 116a are separated from one another in the vertical direction (the Z direction), diffusion between cells may be inhibited, and the reliability of the memory device may be improved.

FIGS. 3A to 3C are a plan view, a cross-sectional view, and a perspective view of a vertical memory device 100b according to an embodiment, respectively. Descriptions with reference to FIGS. 1A to 2C will be briefly given or omitted.

Referring to FIGS. 3A to 3C, the vertical memory device 100b of the present embodiment may include the substrate 102, an electrode structure 110b, the partition pillar 130, the trim patter 140, and the word line cut (WLC). Same descriptions as the substrate 102, the partition pillar 130, the trim pattern 140, and the word line cut (WLC) of the vertical memory device 100 shown in FIGS. 1A to 1C will be applied to the substrate 102, the partition pillar 130, the trim pattern 140, and the word line cut (WLC) of the vertical memory device 100b.

The electrode structures 110b may be arranged in a two-dimensional array structure on a horizontal plane. More particularly, the plurality of electrode structures 110b may constitute a line in the first horizontal direction (the X direction), and the plurality of electrode structures 110b adjacent to each other in the first horizontal direction (the X direction) may be separated from each other by the partition pillar 130. In addition, the electrode structures 110b on two lines adjacent to each other in the second horizontal direction (the Y direction) may be connected to a gate electrode 122b of a gate stack structure 120b. In addition, the plurality of electrode structures 110b constituting the line in the first horizontal direction (the X direction) may be arranged in a zigzag shape in the first horizontal direction (the X direction) on two lines adjacent to each other in the second horizontal direction (the Y direction). That is, in a plan view, the plurality of electrode structures 110b may be arranged in the form of a honeycomb array and/or a hexagonal array. In another embodiment, in a plan view, the plurality of electrode structures 110b may be arranged as a matrix. In other embodiments, the plurality of electrode structures 110b may be arranged in various shapes.

The electrode structure 110b may include the vertical electrode 112, the first carbon layer 114, the switching material layer 116, and a second carbon layer 118b. In some embodiments, at least one of the first carbon layer 114 and the second carbon layer 118b may be omitted. Same descriptions as the vertical electrode 112, the first carbon layer 114, and the switching material layer 116 of the electrode structure 110 of the vertical memory device 100 shown in FIGS. 1A to 1C will be applied to the vertical electrode 112, the first carbon layer 114, and the switching material layer 116.

The second carbon layer 118b may include a plurality of second carbon elements arranged apart from one another by layers in the vertical direction (the Z direction). Each of the second carbon elements may have a shape of two arcs facing each other and surrounding a portion of the switching material layer 116. For example, the second carbon elements of the second carbon layer 118b may be arranged with an arc shape only on layers where the gate electrode 122b of the gate stack structure 120b is located. As shown in FIGS. 2A and 2C, switching material layer 116a may not form a complete circle around partition pillars 130 and carbon layer 114. More particularly, each of the second carbon elements of the second carbon layer 118b may not surround the partition pillars 130 at two sides of the electrode structure 110b in the first horizontal direction (the X direction). Accordingly, the switching material layer 116 may contact the partition pillar 130 in the first horizontal direction (the X direction). The second carbon elements of the second carbon layer 118 may be apart and separated from the second carbon elements on other layers in the vertical direction (the Z direction). Accordingly, the partition pillar 130 may contact each of the switching material layer 116 and the second carbon layer 118b among the components of the electrode structure 110b.

Regarding the vertical memory devices 100, 100a, and 100b of the present embodiments, in the place of an insulating layer having a line shape, the partition pillars 130 having a cylinder shape may be arranged among the electrode structures 110, 110a, and 110b. Accordingly, leaning defect may be effectively prevented despite increase in the number of layers of the gate stack structures 120, 120a, and 120b. In addition, as each of the partition pillars 130 has a cylinder shape, LWR defects may be fundamentally prevented. In addition, open holes to form the word line cut (WLC) and the trim pattern 140 are simultaneously formed through a substantially same process, the vertical memory devices 100, 100a, and 100b of the present embodiments may have an effect of decrease in deviation of electrical performance and/or an effect of decrease in bursting defects.

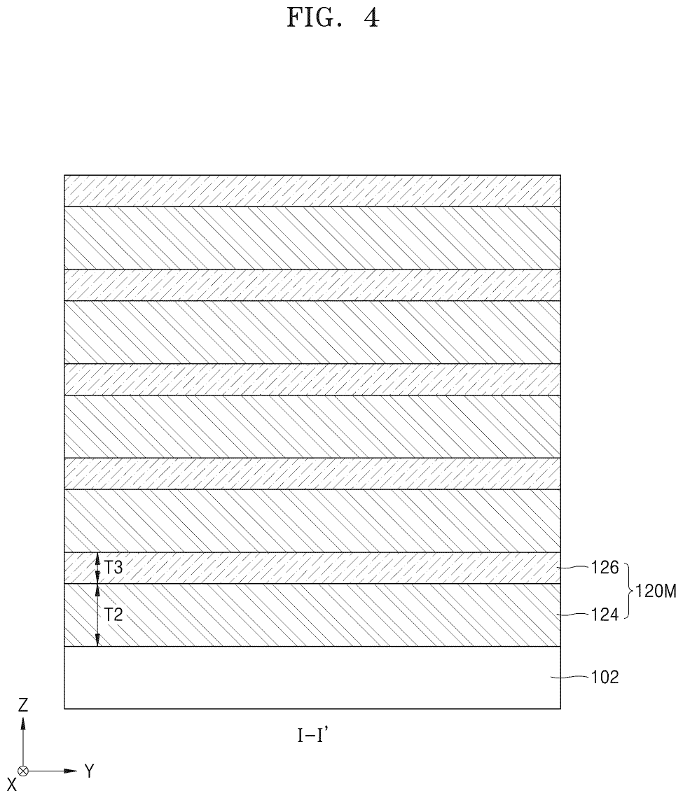

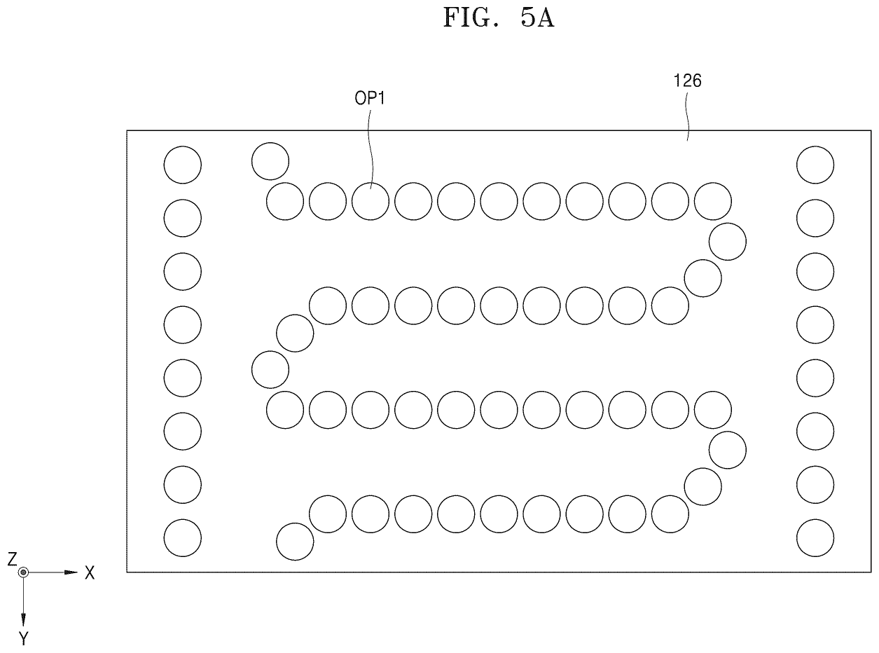

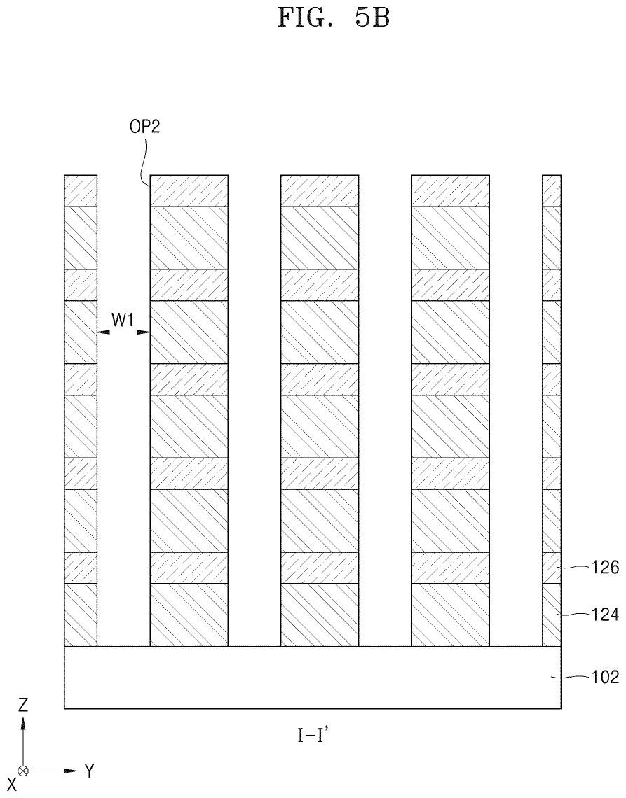

FIGS. 4 to 12B are plan views and cross-sectional views showing processes of manufacturing the vertical memory devices 100, 100b, and 100b shown in FIGS. 1A to 1C. FIGS. 5A, 6A, 7A, 8A, 9A, 10a, 11, and 12A are plan views, and FIGS. 4, 5B, 6B, 7B, 8B, 9B, 10B, and 12B are cross-sectional taken along a line I-I′ shown in FIG. 1A. The aforementioned drawings will be described with reference to FIGS. 1A to 1C, and descriptions with reference to FIGS. 1A to 3C will be briefly given or omitted.

Referring to FIG. 4, first, a mold structure 120M is formed by alternately stacking the interlayer insulating layers 124 and sacrificial insulating layers 126 on the substrate 102. Each of the interlayer insulating layer 124 and the sacrificial insulating layer 126 may include an insulating material. e.g., silicon oxide, silicon nitride, silicon oxynitride, or the like. However, the interlayer insulating layer 124 and the sacrificial insulating layer 126 may include materials having an etching selectivity to each other. For example, in a method of manufacturing the vertical memory device of the present embodiment, the interlayer insulating layer 124 may include silicon oxide, and the sacrificial insulating layer 126 may include silicon nitride. However, as long as the etching selectivity is satisfied, the materials of the interlayer insulating layer 124 and the sacrificial insulating layer 126 are not limited to the aforementioned materials.

Here, the interlayer insulating layer 124 may have the second thickness T2 in the vertical direction (the Z direction), and the sacrificial insulating layer 126 may have a third thickness T3 in the vertical direction (the Z direction). The third thickness T3, i.e., the thickness of the sacrificial insulating layer 126, may be substantially identical to the first thickness T1, that is, the thickness of the gate electrode 122. The second thickness T2 may be greater than the third thickness T3.

Referring to FIGS. 5A and 5B, after forming the mold structure 120M, a plurality of first open holes OP1 are formed in an arrangement shown in FIG. 5A. The plurality of first open holes OP1 may be formed by passing through at least a portion of each of the interlayer insulating layer 124 and the sacrificial insulating layer 126 in the vertical direction (the Z direction). The plurality of first open holes OP1, for example, may have a first horizontal width W1 in the horizontal direction (the X direction and/or the Y direction). The plurality of first open holes OP1 may be arranged apart from each other in the horizontal direction (the X direction and/or the Y direction).

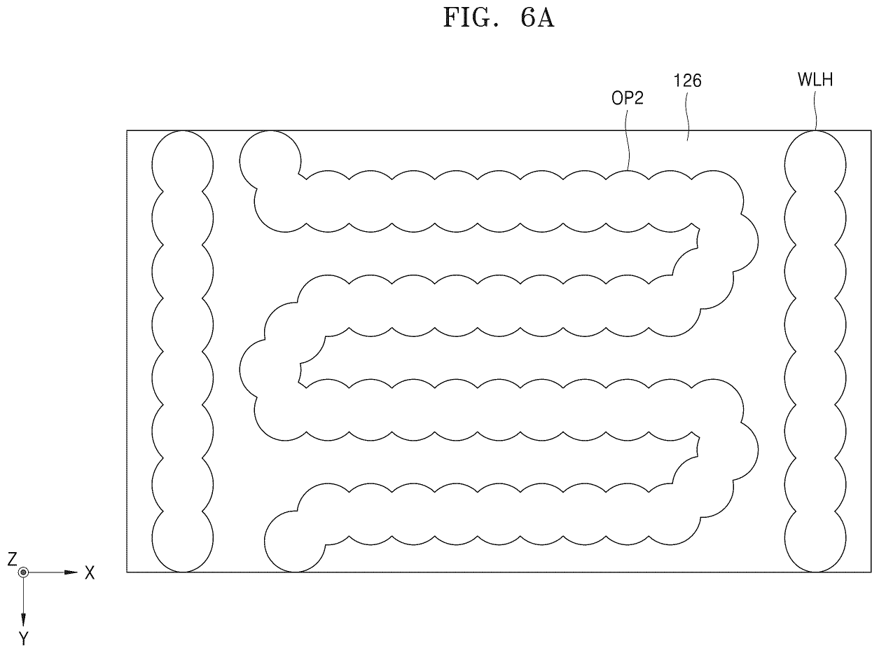

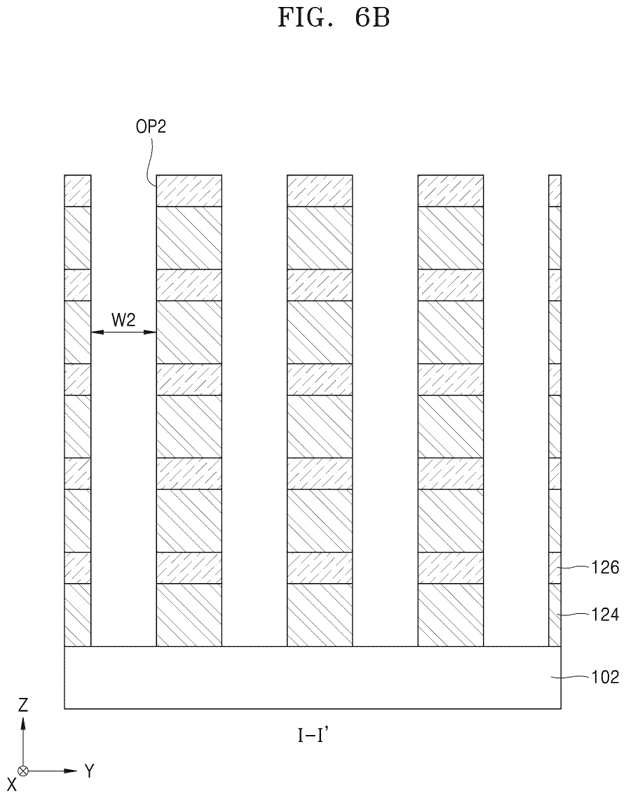

Referring to FIGS. 6A and 6B, a second open hole OP2 and a word line cut hole (WLH) are formed by enlargement of each of the first open holes OP1 in the horizontal direction (the X direction and/or the Y direction). As the second open hole OP2 and the word line cut hole (WLH) are formed by enlargement of the plurality of first open holes OP1, in a plan view, each of the second open hole OP2 and the word line cut hole (WLH) may have a wavy shape.

The second open hole OP2 may include a through hole in which the electrode structure 110, the partition pillar 130, and the trim pattern 140 are to be formed later. In addition, the word line cut hole (WLH) may include a through hole in which the word line cut (WLC) is to be formed later. Accordingly, each of the electrode structure 110, the partition pillar 130, and the trim pattern 140 to be formed later may have a wavy shape on a plane (i.e. wavy-shaped). Likewise, the word line cut (WLC) to be formed later may have a wavy shape on a plane.

The second open hole OP2 and the word line cut hole (WLH) may be arranged apart from each other in the horizontal direction (the X direction and/or the Y direction). As the second open hole OP2 and the word line cut (WLC) are simultaneously formed due to enlargement of the first open hole OP1, the possibility of interference among the partition pillar 130, the trim pattern 140, and the word line cut (WLC) in the horizontal direction (the X direction and/or the Y direction) may be reduced. That is, there may be an effect of reduction in breakage and/or bursting defects of the trim pattern 140 and the word line cut (WLC).

As shown in FIG. 6B, the plurality of second open holes OP2 corresponding to positions at which the electrode structure 110 and/or the partition pillar 130 is formed later may have a second horizontal width W2 in the second horizontal direction (the Y direction). The second horizontal width W2 may be greater than the first horizontal width W1 of the first open hole OP1 shown in FIG. 5B.

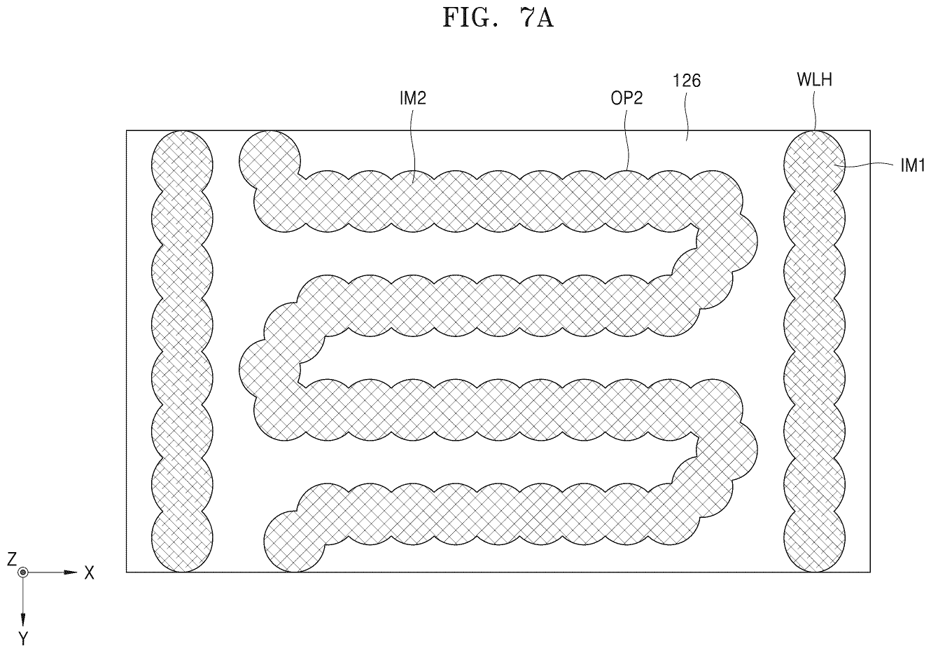

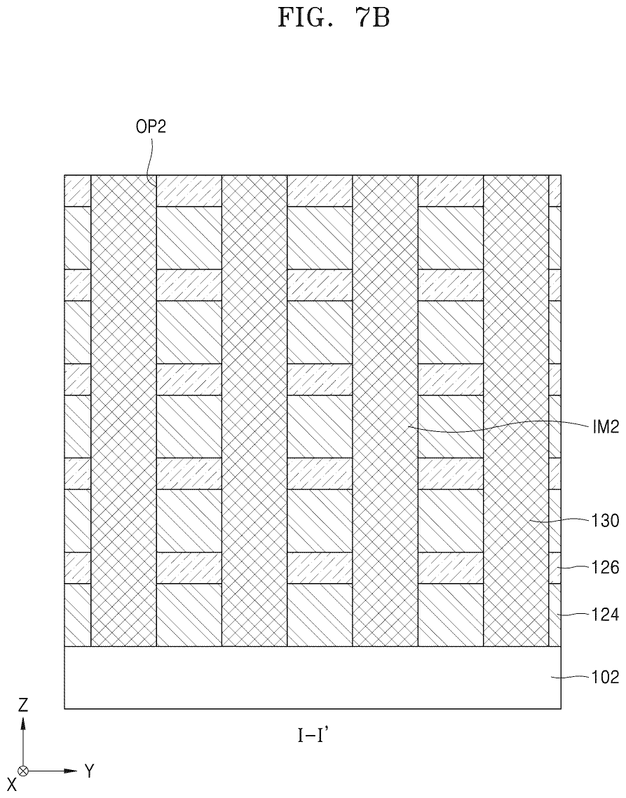

Referring to FIGS. 7A to 7B, after filling the word line cut hole (WLH) with a first insulating material IM1, a top surface of the first insulating material IM1 may be planarized. In addition, after filling the second open hole OP2 with a second insulating material IM2, a top surface of the second insulating material IM2 may be planarized.

In further details, first, the second open hole OP2 and the word line cut hole (WLH) may be filled with the first insulating material IM1, and then the top surface of the first insulating material IM1 may be planarized. Next, after removing the first insulating material IM1 formed in the second open hole OP2, the second open hole OP2 may be filled with the second insulating material IM2, and the top surface of the second insulating material IM2 may be planarized.

For example, the first insulating material IM1 and the second insulating material IM2 may include an oxide material. For example, the first insulating material IM1 and the second insulating material IM2 may include a conductive metal nitride, a conductive metal oxide, silicon oxide, silicon oxynitride, and/or silicon nitride. The second insulating material IM2 may include a material having an etching selectivity with respect to the first insulating material IM1. For example, when the first insulating material IM1 includes silicon oxide, the second insulating material IM2 may include polysilicon.

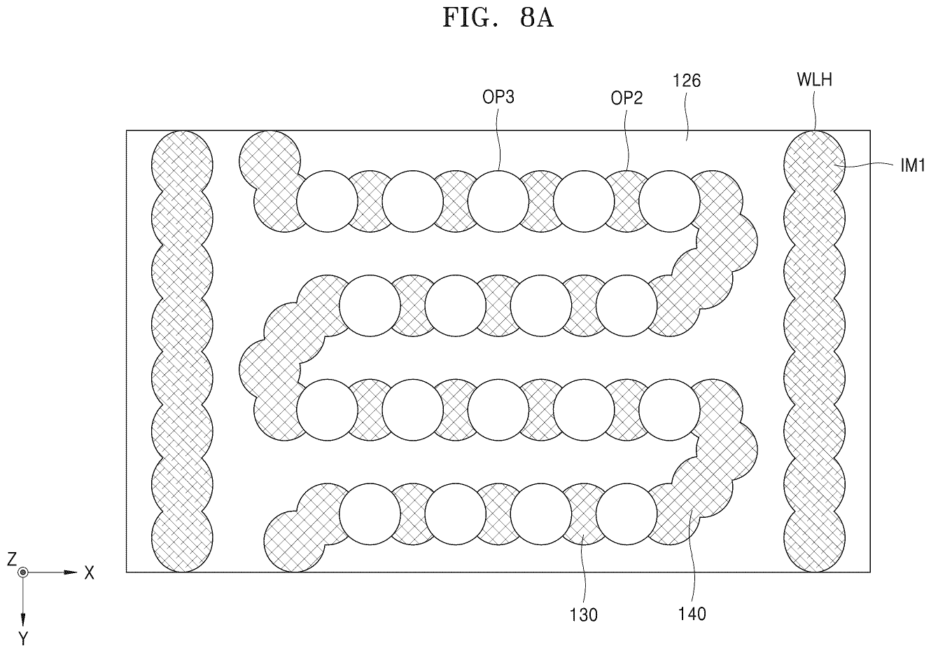

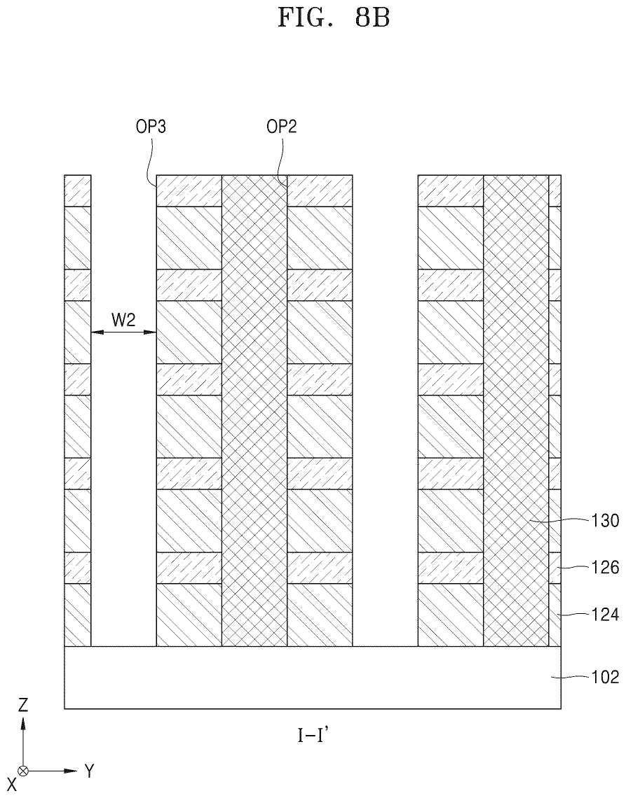

Referring to FIGS. 8A and 8B, a plurality of third open holes OP3 may be formed by removing portions of the second open holes OP2 in the vertical direction (the Z direction). The plurality of third open holes OP3 may be formed by passing through at least a portion of each of the interlayer insulating layer 124 and the sacrificial insulating layer 126 in the vertical direction (the Z direction). The plurality of third open holes OP3, for example, may have a second horizontal width W2 in the horizontal direction (the X direction and/or the Y direction).

The third open hole OP3 may include a through hole for the electrode structure 110. Accordingly, the third open holes OP3 may constitute a line in the first horizontal direction (the X direction) and may be arranged apart from each other. By forming the third open holes OP3, the partition pillar 130 having concave portions (Cc) at two sides in the first horizontal direction (the X direction) may be formed. In addition, by forming the third open holes OP3, the trim patterns 140 may be formed adjacent to an edge of the cell block in the first horizontal direction (the X direction). In a plan view, as the second open hole OP2 has a wavy shape, the trim pattern 140 may also have a wavy shape (i.e. be wavy-shaped).

The plurality of third open holes OP3 may be arranged in a zigzag shape in the first horizontal direction (the X direction) on two lines adjacent to each other in the second horizontal direction (the Y direction). That is, in a plan view, the plurality of third open holes OP3 may be arranged in the form of a honeycomb array and/or a hexagonal array. In another embodiment, in a plan view, the plurality of third open holes OP3 may be arranged in the form of a matrix. In other embodiments, the plurality of third open holes OP3 may be arranged in various shapes.

FIGS. 8A and 8B illustrate embodiments in which the second insulating material IM2 includes materials of the partition pillar 130 and the trim pattern 140, the disclosure is not limited thereto. For example, the partition pillar 130 and/or the trim pattern 140 may be formed by removing the second insulating material IM2 and filling the portion, from which the second insulating material IM2 is removed, with the material of the partition pillar 130 and/or the trim pattern 140.

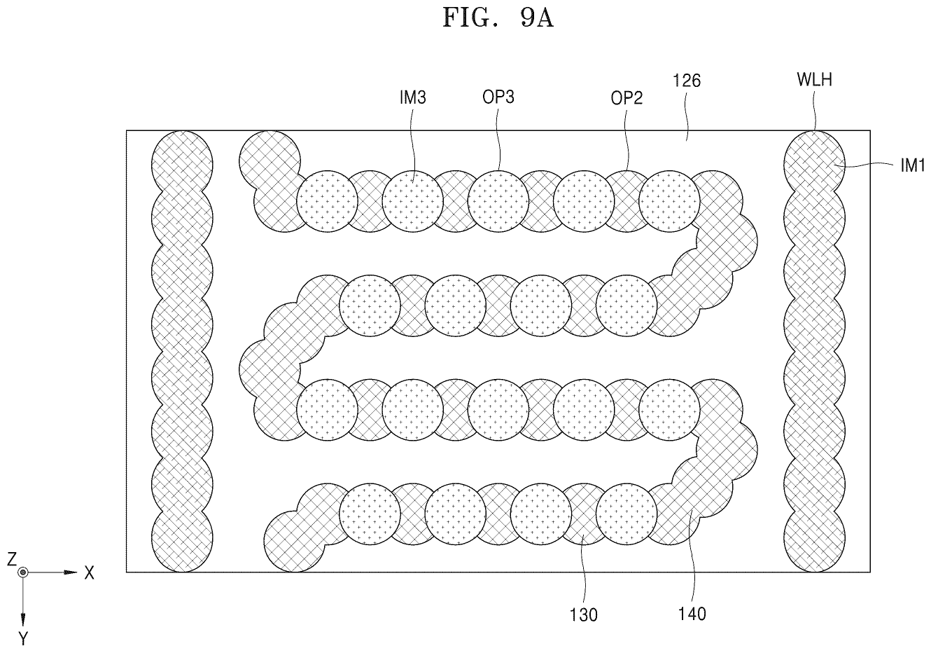

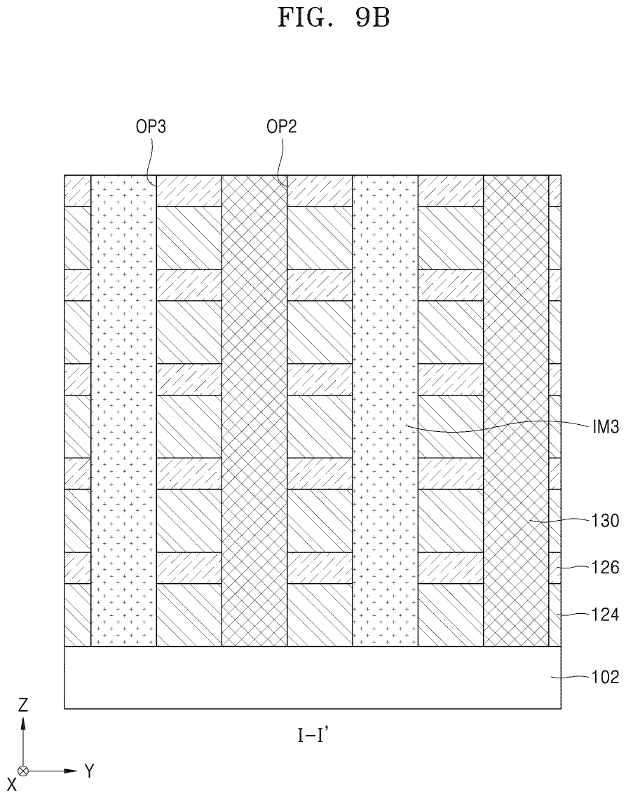

Referring to FIGS. 9A and 9B, after forming the third open hole OP3, the third open hole OP3 is filled with a third insulating material IM3, and a top surface of the third insulating material IM3 is planarized. For example, the third insulating material IM3 may include an oxide material. For example, the third insulating material IM3 may include a conductive metal nitride, a conductive metal oxide, silicon oxide, silicon oxynitride, and/or silicon nitride. The third insulating material IM3 may include a material having an etching selectivity with respect to each of the first insulating material IM1 and the second insulating material IM2.

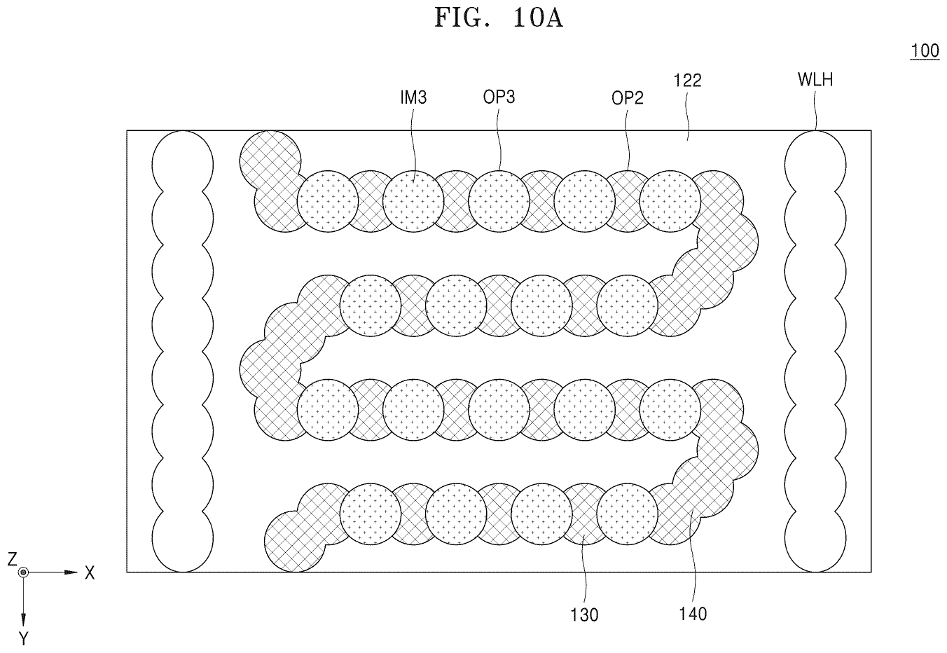

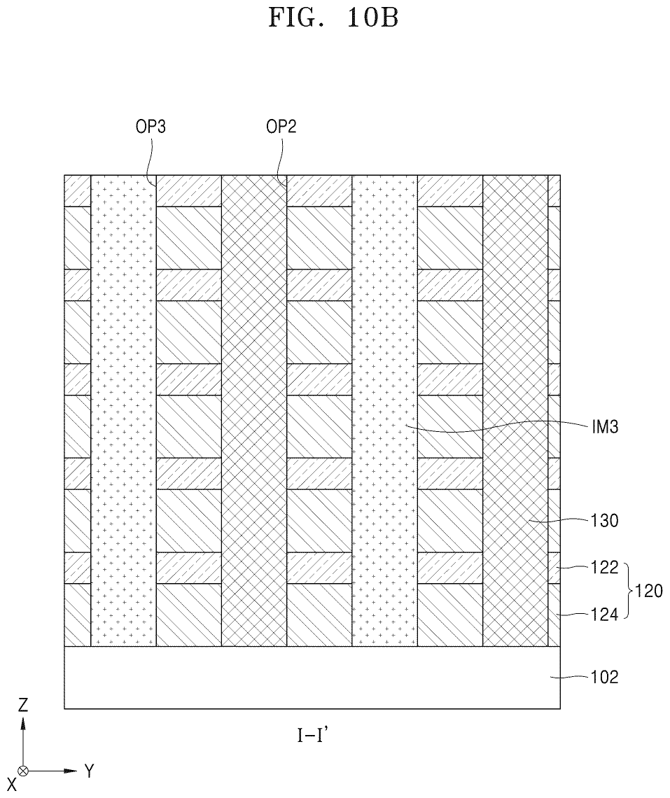

Referring to FIGS. 10A and 10B, the sacrificial insulating layer 126 is changed into the gate electrode 122 through a replacement process. For example, to perform the replacement process, the first insulating material IM1 (see FIG. 9A) formed in the word line cut hole (WLH) may be removed, and the interlayer insulating layer 124 and the sacrificial insulating layer 126 may be exposed through a sidewall of the word line cut hole (WLH). Next, the gate electrode 122 may be formed by performing wet etching to remove the sacrificial insulating layer 126 that has been exposed and filling a portion, from which the sacrificial insulating layer 126 has been removed, with a conductive material. Here, the conductive material may include, for example, a doped semiconductor material, a metal, a conductive metal nitride, a conductive metal oxide, and the like.

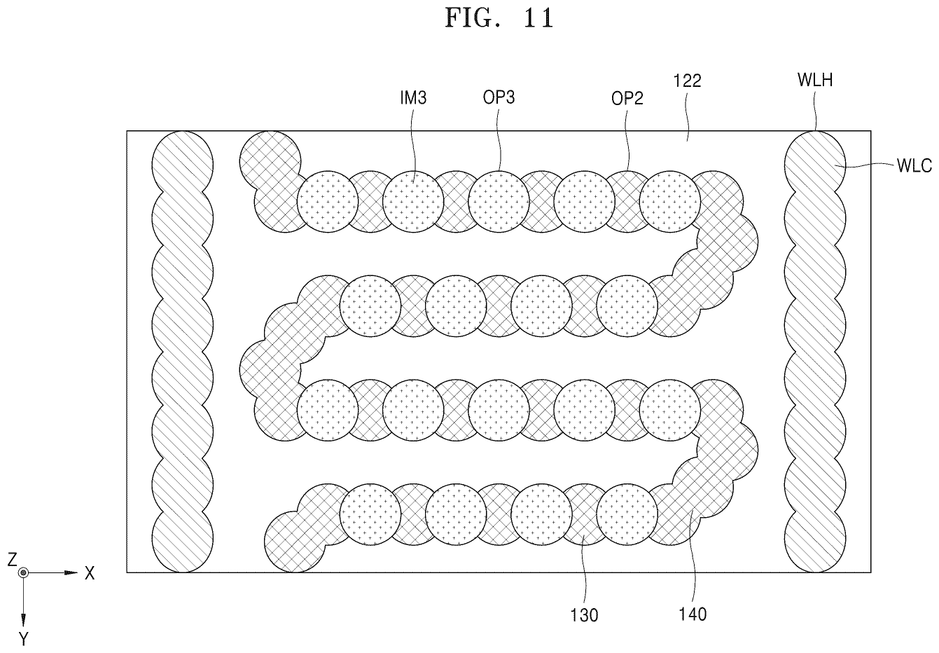

Referring to FIG. 11, the word line cut (WLC) may be formed in the word line cut hole (WLH). The word line cut (WLC) may include an insulating material. For example, the word line cut (WLC) may include an oxide or/a nitride. The word line cut (WLC) may define a cell block.

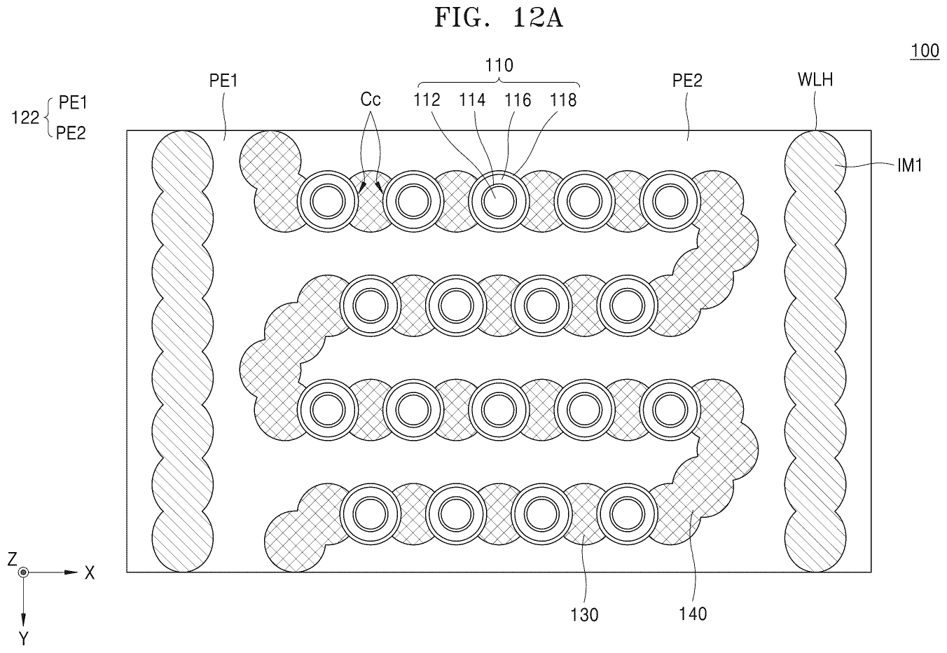

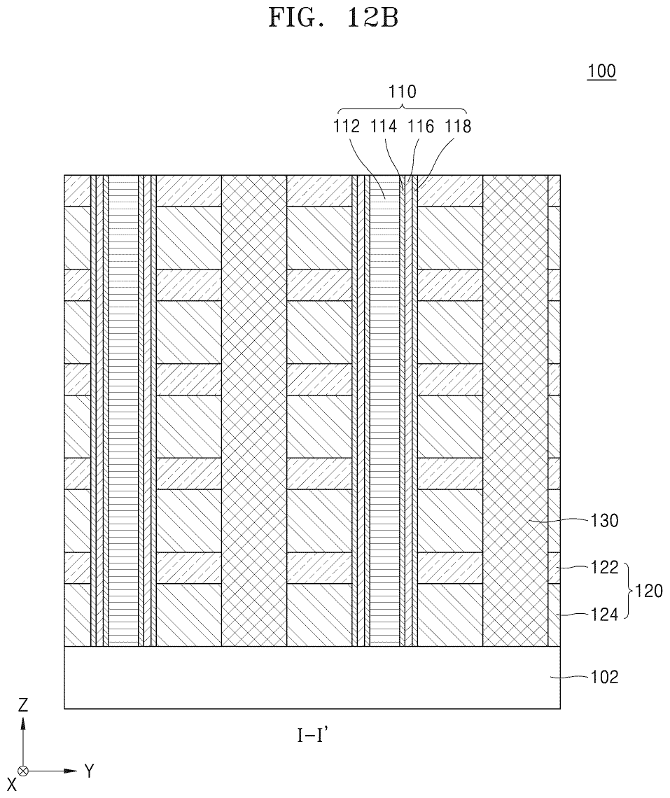

Referring to FIGS. 12A and 12B, the electrode structure 110 may be formed by removing the third insulating material IM3 formed in the third open hole OP3 (see FIG. 11) and sequentially forming the second carbon layer 118, the switching material layer 116, the first carbon layer 114, and the vertical electrode 112 in the third open hole OP3 (see FIG. 11).

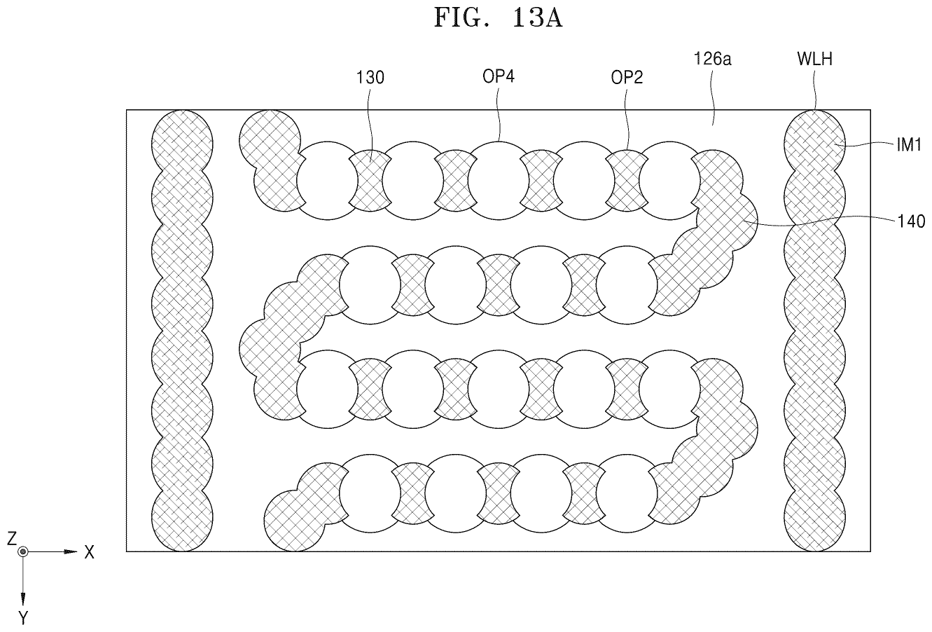

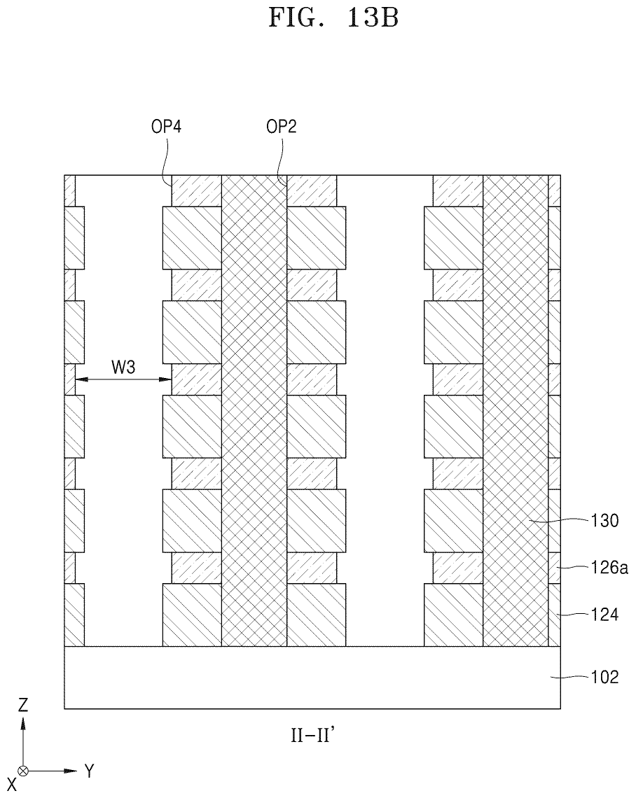

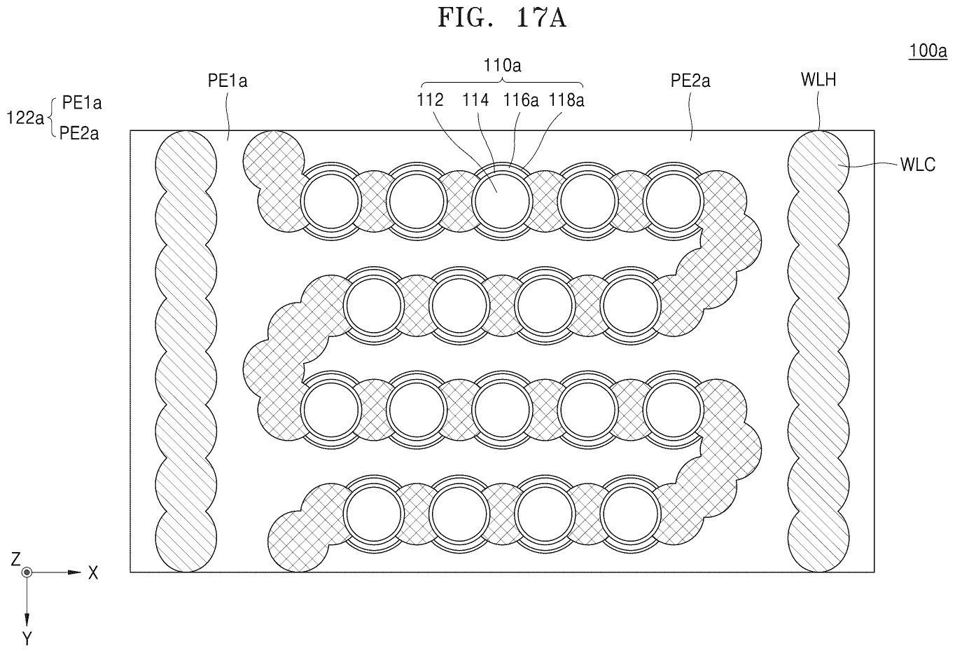

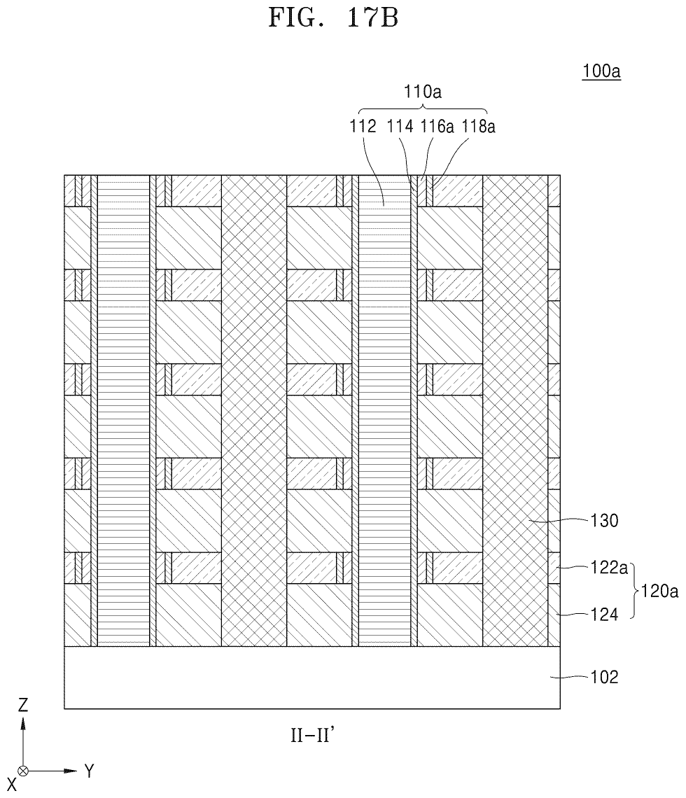

FIGS. 13A to 17B are plan views and cross-sectional views showing processes of manufacturing the vertical memory device 100a shown in FIGS. 2A and 2B. FIGS. 13A, 14A, and 17A are plan views, and FIGS. 13B, 14B, 15, 16, and 17B are cross-sectional views taken along a line II-II′ shown in FIG. 2A. The aforementioned drawings will be described with reference to FIGS. 2A to 2C, and descriptions with reference to FIGS. 4 to 12B will be briefly given or omitted.

Referring to FIGS. 13A and 13B, in a product shown in FIGS. 8A and 8B, a portion of the sacrificial insulating layer 126 exposed through the third open hole OP3 (see FIG. 8A) is etched in an etching process. By etching the portion the sacrificial insulating layer 126, a fourth open hole OP4, in which recesses are formed at two sides in the second horizontal direction (the Y direction), may be formed.

After the recesses have been formed, in the recesses of the fourth open hole OP4, a width in the second horizontal direction (the Y direction) may include a third horizontal width W3, and the third horizontal width W3 may be greater than the second horizontal width W2. The third horizontal width W3 may be appropriately adjusted in consideration of a total size, i.e., a diameter, of the electrode structure 110a to be formed later. As the partition pillars 130 are at two sides of the fourth open hole OP4 in the first horizontal direction (the X direction), the width of the fourth open hole OP4 in the first horizontal direction (the X direction) may not increase or may increase very little. That is, the width in the horizontal direction (the X direction and/or the Y direction) in a direction in which the partition pillar 130 is located may not increase, or may increase very little.

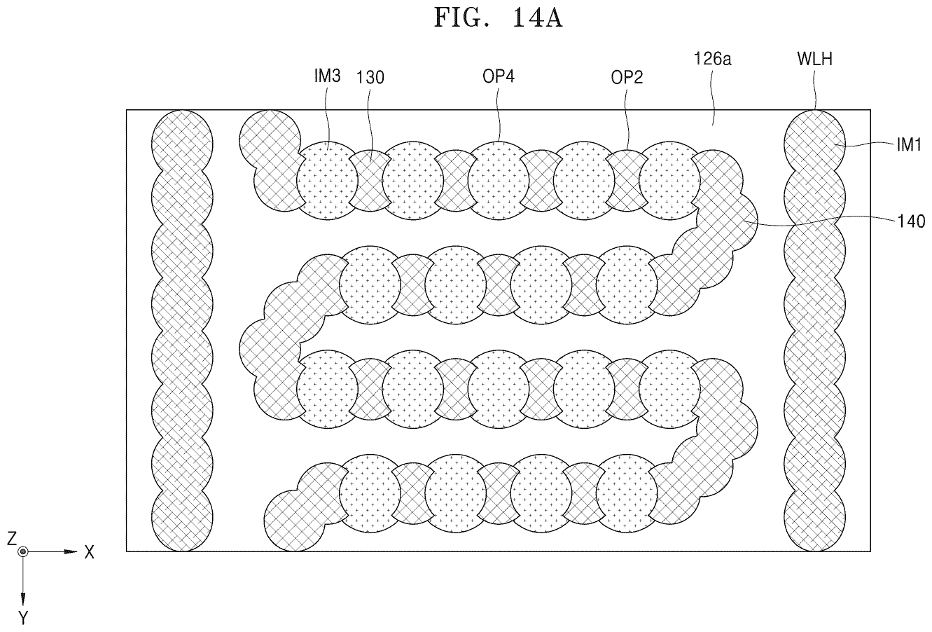

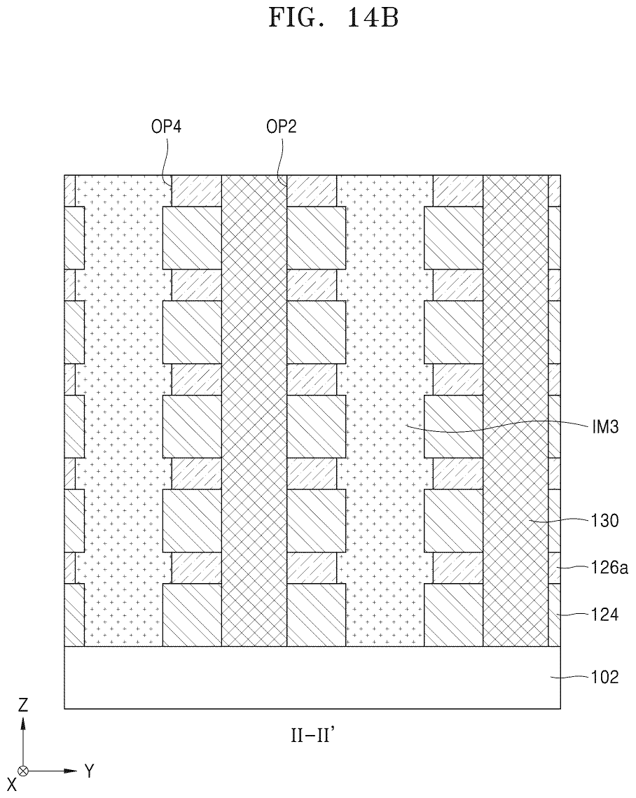

Referring to FIGS. 14A and 14B, like in FIGS. 9A and 9B, a fourth hole OP4 is filled with the third insulating material IM3, and a top surface of the third insulating material IM3 is planarized. For example, the third insulating material IM3 may include an oxide material. For example, the third insulating material IM3 may include a conductive metal nitride, a conductive metal oxide, silicon oxide, silicon oxynitride, and/or silicon nitride. The third insulating material IM3 may include a material having an etching selectivity with respect to each of the first insulating material IM1 and the second insulating material IM2.

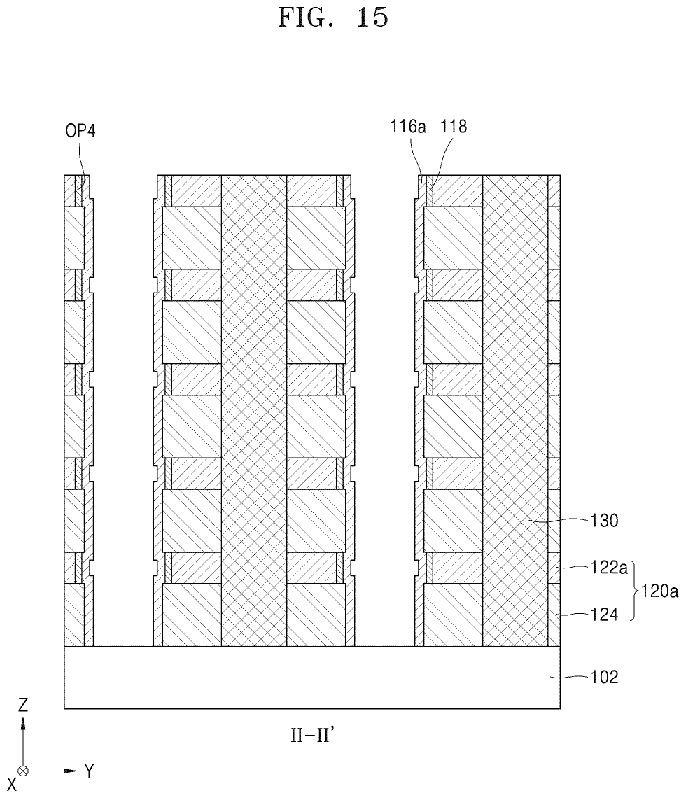

Referring to FIGS. 15 to 17B, first, the first insulating material IM1 (see FIG. 14A) formed in the word line cut hole (WLH) is removed, and the sacrificial insulating layer 126a (see FIG. 14A) is changed into the gate electrode 122a through a replacement operation. Next, after forming the word line cut (WLC) in the word line cut hole (WLH), the third insulating material IM3 (see FIG. 14A) formed in the fourth open hole OP4 is removed, and the second carbon layer 118a, the second carbon layer 118a, the first carbon layer 114, and the vertical electrode 112 are sequentially formed in the fourth open hole OP4, and thus, the electrode structure 110a may be formed. Operation of the memory device according to this embodiment is as described above with reference to FIGS. 10A to 12B.

To further describe a process of forming the electrode structure 110a in the fourth open hole OP4, first, the second carbon layer 118a and a preliminary switching material layer 116a′ are sequentially formed in the fourth open hole OP4. As the fourth open hole OP4 includes recesses, the preliminary switching material layer 116a′ may have curves in the fourth open hole OP4.

Thereafter, in the fourth open hole OP4, the preliminary switching material layer 116′ protruded by the interlayer insulating layer 124 is removed by etching. The etching may include, for example, etch-back, dry etching, and the like. Through the etching process, the switching material layer 116a and the second carbon layer 118a may be formed only in a recess of each layer.

When a protrusion portion of the preliminary switching material layer 116′ is referred to as a spacer, an etching process to remove the protrusion portion may be referred to as a spacer etching process. In addition, as the preliminary switching material layers 116a′ between the layers are separated from each other through the etching process, the etching process to remove the protrusion portion may also be referred to a separation etching process. Here, the etching processes will be collectively referred to as a spacer etching process.

After the spacer etching process, the third open hole OP3 may be formed again. Next, the vertical memory device 100a shown in FIGS. 2A to 2C is complete by sequentially forming the first carbon layer 114 and the vertical electrode 112 in the third open hole OP3.

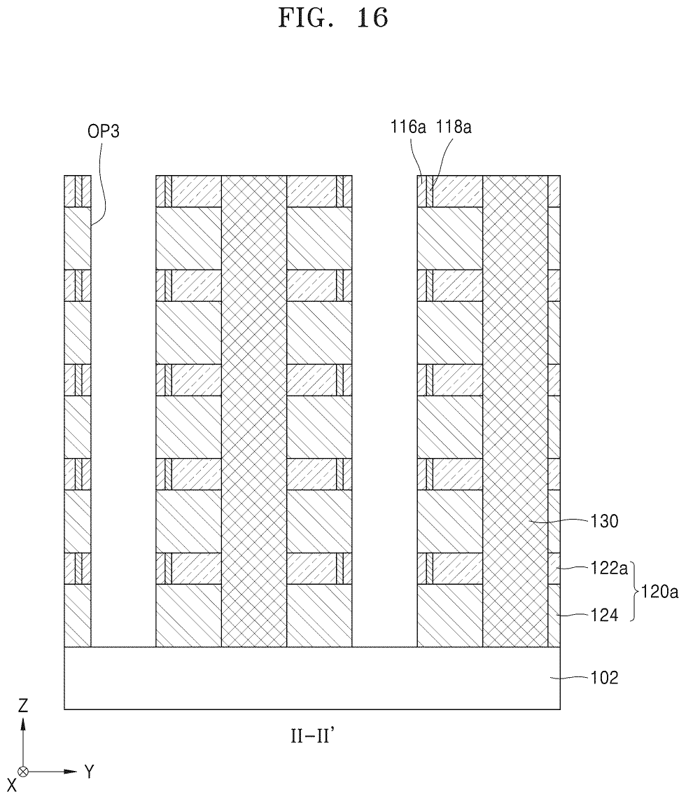

In addition, to briefly describe a process of manufacturing the vertical memory device 100b shown in FIGS. 3A to 3C, in a process shown in FIGS. 13A to 13B, the recesses are formed in a very small width. The gate electrode 122c is formed through the processes shown in FIGS. 14A and 14B. In a process corresponding to the illustration of FIG. 15, the second carbon layer 118b is formed. In a process corresponding to the illustration of FIG. 16, the second carbon layer 118b is maintained only in the recess through the spacer etching process. Next, the vertical memory device 100b shown in FIGS. 3A to 3C is complete by sequentially forming the switching material layer 116, the first carbon layer 114, and the vertical electrode 112 on the second carbon layer 118b.

While certain embodiments the disclosure have been particularly shown and described, it will be understood that various changes in form and details may be made therein without departing from the spirit and scope of the following claims.

What is claimed is:

1. A vertical memory device comprising:
a substrate;
a plurality of electrode structures extending in a vertical direction on the substrate;
a word line cut disposed apart from the plurality of electrode structures in a horizontal direction and extending in the vertical direction; and
a gate stack structure comprising gate electrodes and interlayer insulating layers alternately stacked on the substrate along a sidewall of each of the plurality of electrode structures and the word line cut, wherein the gate electrodes are electrically connected to the plurality of electrode structures,
wherein, in a plan view, the word line cut is wavy-shaped.

2. The vertical memory device of claim 1, wherein the plurality of electrode structures constitute a plurality of lines in a first horizontal direction, and
the word line cut extends in a second horizontal direction perpendicular to the first horizontal direction.

3. The vertical memory device of claim 1, wherein the plurality of electrode structures are disposed apart from each other in a first horizontal direction, further comprising:
a plurality of partition pillars each disposed between the plurality of electrode structures, and passing through at least a portion of the gate stack structure in the vertical direction.

4. The vertical memory device of claim 3, wherein, in the plan view, each of the plurality of electrode structures has a circular cross-section, and each of the plurality of partition pillars comprises concave portions in the first horizontal direction.

5. The vertical memory device of claim 3, wherein, in the plan view, the plurality of electrode structures and the plurality of partition pillars are wavy-shaped.

6. The vertical memory device of claim 1, wherein, in the plan view, the plurality of electrode structures are disposed in a hexagonal array.

7. A vertical memory device comprising:
a substrate;
a plurality of electrode structures extending in a vertical direction on the substrate and constituting a plurality of lines in a first horizontal direction;
a plurality of partition pillars extending on the substrate in the vertical direction and contacting at least one of the plurality of electrode structures;
a word line cut disposed apart from the plurality of electrode structures in a horizontal direction and extending in the vertical direction; and
a gate stack structure comprising gate electrodes and interlayer insulating layers alternately stacked on the substrate along a sidewall of each of the plurality of electrode structures and the word line cut, wherein the gate electrodes are electrically connected to the plurality of electrode structures,
wherein, in a plan view, the word line cut is wavy-shaped, and
wherein each of the plurality of electrode structures comprises:
a vertical electrode extending in the vertical direction on the substrate; and
a switching material layer surrounding the vertical electrode and extending in the vertical direction.

8. The vertical memory device of claim 7, wherein the switching material layer has a circular pipe shape surrounding the vertical electrode and extending in the vertical direction.

9. The vertical memory device of claim 7, wherein the switching material layer comprises a plurality of switching elements disposed apart from one another by layer in the vertical direction, and
wherein each of the plurality of switching elements has a shape of two arcs facing each other and surrounding the vertical electrode.

10. The vertical memory device of claim 7, further comprising:
a first carbon layer disposed between the vertical electrode and the switching material layer; and
a second carbon layer disposed between the gate electrodes and the switching material layer.

11. The vertical memory device of claim 10, wherein the first carbon layer and the second carbon layer have a circular pipe shape.

12. The vertical memory device of claim 10, wherein the first carbon layer has a circular pipe shape, and
wherein the second carbon layer comprises second carbon elements corresponding to switching elements, and each of the second carbon elements has a shape of two arcs.

13. The vertical memory device of claim 7, wherein a bottom surface of the vertical electrode, bottom surfaces of the plurality of partition pillars, and a bottom surface of the gate stack structure are at a same vertical level.

14. A vertical memory device comprising:
a substrate;
a plurality of electrode structures extending in a vertical direction on the substrate and constituting a plurality of lines in a first horizontal direction;
a plurality of partition pillars each extending on the substrate in the vertical direction and contacting at least one of the plurality of electrode structures;
a plurality of trim patterns contacting the plurality of electrode structures or the plurality of partition pillars and extending in the vertical direction on the substrate;
a word line cut disposed apart from each of the plurality of electrode structures, the plurality of partition pillars, and the plurality of trim patterns in a horizontal direction and extending in the vertical direction; and
a gate stack structure comprising gate electrodes and interlayer insulating layers alternately stacked on the substrate along a sidewall of each of the plurality of electrode structures, the plurality of partition pillars, and the word line cut, wherein the gate electrodes are electrically connected to the plurality of electrode structures,
wherein, in a plan view, each of the plurality of trim patterns and the word line cut are wavy shaped,
wherein the plurality of electrode structures and the plurality of partition pillars form a plurality of sub channels extending in the first horizontal direction,
wherein the plurality of trim patterns form a connection channel connecting the plurality of sub channels that are apart from each other in a second horizontal direction, and
wherein each of the plurality of electrode structures comprises:
a vertical electrode extending in the vertical direction on the substrate; and
a switching material layer surrounding the vertical electrode and extending in the vertical direction.

15. The vertical memory device of claim 14, further comprising:
a first carbon layer disposed between the vertical electrode and the switching material layer; and
a second carbon layer disposed between each of the gate electrodes and the switching material layer.

16. The vertical memory device of claim 14, wherein each of the gate electrodes comprises a first plate electrode and a second plate electrode disposed apart from each other in the horizontal direction and disposed at a same vertical level,
wherein the first plate electrode and the second plate electrode each have a comb shape comprising a plurality of protrusion electrode portions, and
wherein each of the plurality of electrode structures contact a protrusion portion of the first plate electrode and a protrusion portion of the second plate electrode.

17. The vertical memory device of claim 14, wherein a first thickness of each of the interlayer insulating layers in the vertical direction is greater than a second thickness of each of the gate electrodes in the vertical direction.

18. The vertical memory device of claim 14, wherein, in the plan view, the plurality of electrode structures, the plurality of partition pillars, and the plurality of trim patterns have a serpentine line shape.

19. The vertical memory device of claim 14, wherein a first trim pattern and a second trim pattern are disposed apart from each other in the first horizontal direction at staggered positions in the second horizontal direction.

20. The vertical memory device of claim 14, wherein, in the plan view, the plurality of electrode structures, the plurality of partition pillars, and the plurality of trim patterns are wavy-shaped.
